(19) United States
(12) Patent Application Publication
(10) Pub. No.: US 2025/0151345 A1
(43) Pub. Date: May 8, 2025

(54) MODULE-LESS NANOSHEET FETS WITH DIRECT BACKSIDE CONTACT

(71) Applicant: International Business Machines Corporation, Armonk, NY (US)

(72) Inventors: Ruilong Xie, Niskayuna, NY (US); Dureseti Chidambarrao, Weston, CT (US); John Christopher Arnold, North Chatham, NY (US); Julien Frougier, Albany, NY (US)

(21) Appl. No.: 18/388,074

(22) Filed: Nov. 8, 2023

(51) Int. Cl. H01L 29/06; H01L 23/48; H01L 27/092; H01L 29/417; H01L 29/423; H01L 29/775; H01L 29/786

(52) U.S. Cl. CPC H10D 62/121; H01L 23/481; H10D 30/43; H10D 30/6729; H10D 30/6735; H10D 30/6757; H10D 84/85

(57) ABSTRACT

A semiconductor device is provided including NS-FETs in which the active area module, the shallow trench isolation module and the gate module are eliminated from the processing of the semiconductor device. The elimination of these modules makes the overall process easier and aids in reducing the cost of manufacturing the semiconductor device.

### BACKGROUND

The present application relates to semiconductor technology, and more particularly to a semiconductor device including nanosheet field effect transistors (NS-FETs) in which the active area module, the shallow trench isolation module and the gate module are eliminated from the process of forming the semiconductor device.

Incessant downscaling of feature size of multi-gate devices such as FinFETs and gate-all-around (GAA) nanowire (NW)-FETs leads to unadorned effects such, as for example, short channel effects (SCEs) which limits their performance and causes reliability issues. FinFET technology has resulted in a remarkable performance up to a feature size of 7 nm. However, further shrinking of feature size to 3 nm will impose severe challenges to the performance of these previously mentioned multi-gate devices. Subsequently, semiconductor industry has been investigating alternative device designs such as, for example, NS-FETs to overcome the limitations of the FinFET and GAA NW-FETs technologies. The driving force behind the emergence of NS-FETs is their ability to scale down even below a feature size of 5 nm with negligible short channel effects.

### SUMMARY

A semiconductor device is provided including NS-FETs in which the active area module, the shallow trench isolation module and the gate module are eliminated from the processing of the semiconductor device. The elimination of these modules makes the overall process easier and aids in reducing the cost of manufacturing the semiconductor device.

In one aspect of the present application, a semiconductor device is provided. In one embodiment of the present application, the semiconductor device includes a first complementary metal oxide semiconductor (CMOS) cell including a first pair of complementary nanosheet field effect transistors including a first shared gate structure and a second CMOS cell including a second pair of complementary nanosheet field effect transistors including a second shared gate structure. The device further includes a first dielectric material pillar having a first height separating the first shared gate structure of the first CMOS cell from the second shared gate structure of the second CMOS cell, and a second dielectric material pillar having a second height that is less than the first height, wherein the second dielectric material pillar is located between the complementary nanosheet field effect transistors of both the first pair of complementary nanosheet field effect transistors and the second pair of complementary nanosheet field effect transistors. The device even further includes a hard mask cap located above each of the complementary nanosheet field effect transistors of both the first pair of complementary nanosheet field effect transistors and the second pair of complementary nanosheet field effect transistors, wherein the hard mask cap has outermost edges that are substantially vertically aligned to outermost edges of each semiconductor channel material nanosheet of the complementary nanosheet field effect transistors of the first pair of complementary nanosheet field effect transistors and the second pair of complementary nanosheet field effect transistors in a direction perpendicular to both the first shared gate structure and the second shared gate structure, and the hard mask cap extends horizontally beyond each semiconductor channel material nanosheet of the complementary nanosheet field effect transistors of the first pair of complementary nanosheet field effect transistors and the second pair of complementary nanosheet field effect transistors in a direction parallel to the both the first shared gate structure and the second shared gate structure. The device yet further includes a dielectric material cap extending outward from each of the outermost edges of the hard mask cap in the direction parallel to the both the first shared gate structure and the second shared gate structure.

In another aspect a process of forming a semiconductor device is provided in which active area module, shallow trench isolation module and gate module are eliminated from the processing flow.

### BRIEF DESCRIPTION OF THE DRAWINGS

FIG. 1A is a top down view of an exemplary semiconductor structure that can be employed in the present application, the exemplary semiconductor substrate including a material stack located on a substrate, and a hard mask layer located on the material stack, wherein the material stack includes alternating sacrificial semiconductor material layers and semiconductor channel material layers; FIG. 1A includes cuts X-X, Y1-Y1 and Y2-Y2.

FIGS. 1B, 1C and 1D are cross sectional views of the exemplary semiconductor structure shown in FIG. 1A and through cuts X-X, Y1-Y1 and Y2-Y2, respectively.

FIG. 2A is a top down view of the exemplary semiconductor structure shown in FIG. 1A after gate cut patterning; FIG. 2A includes cuts X-X, Y1-Y1 and Y2-Y2.

FIGS. 2B, 2C and 2D are cross sectional views of the exemplary semiconductor structure shown in FIG. 2A and through cuts X-X, Y1-Y1 and Y2-Y2, respectively.

FIG. 3A is a top down view of the exemplary semiconductor structure shown in FIG. 2A after forming a sacrificial spacer; FIG. 3A includes cuts X-X, Y1-Y1 and Y2-Y2.

FIGS. 3B, 3C and 3D are cross sectional views of the exemplary semiconductor structure shown in FIG. 3A and through cuts X-X, Y1-Y1 and Y2-Y2, respectively.

FIG. 4A is a top down view of the exemplary semiconductor structure shown in FIG. 3A after forming a dielectric material pillar adjacent to each sacrificial spacer; FIG. 4A includes cuts X-X, Y1-Y1 and Y2-Y2.

FIGS. 4B, 4C and 4D are cross sectional views of the exemplary semiconductor structure shown in FIG. 4A and through cuts X-X, Y1-Y1 and Y2-Y2, respectively.

FIG. 5A is a top down view of the exemplary semiconductor structure shown in FIG. 4A after first S/D type patterning; FIG. 5A includes cuts X-X, Y1-Y1 and Y2-Y2.

FIGS. 5B, 5C and 5D are cross sectional views of the exemplary semiconductor structure shown in FIG. 5A and through cuts X-X, Y1-Y1 and Y2-Y2, respectively.

FIG. 6A is a top down view of the exemplary semiconductor structure shown in FIG. 5A after selective hard mask cap removal; FIG. 6A includes cuts X-X, Y1-Y1 and Y2-Y2.

FIGS. 6B, 6C and 6D are cross sectional views of the exemplary semiconductor structure shown in FIG. 6A and through cuts X-X, Y1-Y1 and Y2-Y2, respectively.

FIG. 7A is a top down view of the exemplary semiconductor structure shown in FIG. 6A after selective sacrificial semiconductor material nanosheet removal; FIG. 7A includes cuts X-X, Y1-Y1 and Y2-Y2.

FIGS. 7B, 7C and 7D are cross sectional views of the exemplary semiconductor structure shown in FIG. 7A and through cuts X-X, Y1-Y1 and Y2-Y2, respectively.

FIG. 8A is a top down view of the exemplary semiconductor structure shown in FIG. 7A after nanosheet recessing, indentation of the sacrificial semiconductor material nanosheets, first inner spacer formation, and formation of a first type of source/drain region; FIG. 8A includes cuts X-X, Y1-Y1 and Y2-Y2.

FIGS. 8B, 8C and 8D are cross sectional views of the exemplary semiconductor structure shown in FIG. 8A and through cuts X-X, Y1-Y1 and Y2-Y2, respectively.

FIG. 9A is a top down view of the exemplary semiconductor structure shown in FIG. 7A after forming a first frontside interlayer dielectric (ILD) layer; FIG. 9A includes cuts X-X, Y1-Y1 and Y2-Y2.

FIGS. 9B, 9C and 9D are cross sectional views of the exemplary semiconductor structure shown in FIG. 9A and through cuts X-X, Y1-Y1 and Y2-Y2, respectively.

FIG. 10A is a top down view of the exemplary semiconductor structure shown in FIG. 7A after second S/D type patterning; FIG. 10A includes cuts X-X, Y1-Y1 and Y2-Y2.

FIGS. 10B, 10C and 10D are cross sectional views of the exemplary semiconductor structure shown in FIG. 10A and through cuts X-X, Y1-Y1 and Y2-Y2, respectively.

FIG. 11A is a top down view of the exemplary semiconductor structure shown in FIG. 10A after selective hard mask cap removal and selective sacrificial semiconductor material nanosheet removal; FIG. 11A includes cuts X-X, Y1-Y1 and Y2-Y2.

FIGS. 11B, 11C and 11D are cross sectional views of the exemplary semiconductor structure shown in FIG. 11A and through cuts X-X, Y1-Y1 and Y2-Y2, respectively.

FIG. 12A is a top down view of the exemplary semiconductor structure shown in FIG. 11A after nanosheet recessing, indentation of the sacrificial semiconductor material nanosheets, second inner spacer formation, and formation of a backside source/drain contact placeholder structure and a second type of source/drain region; FIG. 12A includes cuts X-X, Y1-Y1 and Y2-Y2.

FIGS. 12B, 12C and 12D are cross sectional views of the exemplary semiconductor structure shown in FIG. 12A and through cuts X-X, Y1-Y1 and Y2-Y2, respectively.

FIG. 13A is a top down view of the exemplary semiconductor structure shown in FIG. 2A after forming a second frontside ILD layer; FIG. 13A includes cuts X-X, Y1-Y1 and Y2-Y2.

FIGS. 13B, 13C and 13D are cross sectional views of the exemplary semiconductor structure shown in FIG. 13A and through cuts X-X, Y1-Y1 and Y2-Y2, respectively.

FIG. 14A is a top down view of the exemplary semiconductor structure shown in FIG. 2A after replacement gate patterning lithography; FIG. 14A includes cuts X-X, Y1-Y1 and Y2-Y2.

FIGS. 14B, 14C and 14D are cross sectional views of the exemplary semiconductor structure shown in FIG. 14A and through cuts X-X, Y1-Y1 and Y2-Y2, respectively.

FIG. 15A is a top down view of the exemplary semiconductor structure shown in FIG. 2A after replacement gate patterning; FIG. 15A includes cuts X-X, Y1-Y1 and Y2-Y2.

FIGS. 15B, 15C and 15D are cross sectional views of the exemplary semiconductor structure shown in FIG. 15A and through cuts X-X, Y1-Y1 and Y2-Y2, respectively.

FIG. 16A is a top down view of the exemplary semiconductor structure shown in FIG. 15A after removing the sacrificial spacer and the sacrificial semiconductor material nanosheets and forming a gate structure; FIG. 16A includes cuts X-X, Y1-Y1 and Y2-Y2.

FIGS. 16B, 16C and 16D are cross sectional views of the exemplary semiconductor structure shown in FIG. 16A and through cuts X-X, Y1-Y1 and Y2-Y2, respectively.

FIG. 17A is a top down view of the exemplary semiconductor structure shown in FIG. 16A after forming an additional frontside ILD layer to provide a middle-of-the line (MOL) dielectric layer, forming frontside contact structures, a frontside back-end-of-the-line (BEOL) structure, and a carrier wafer; FIG. 17A includes cuts X-X, Y1-Y1 and Y2-Y2.

FIGS. 17B, 17C and 17D are cross sectional views of the exemplary semiconductor structure shown in FIG. 17A and through cuts X-X, Y1-Y1 and Y2-Y2, respectively.

FIGS. 18A, 18B and 18C are cross sectional views of the exemplary semiconductor structure shown in FIGS. 17B, 17C and 17D, respectively, after removing the first semiconductor layer of the substrate.

FIGS. 19A, 19B and 19C are cross sectional views of the exemplary semiconductor structure shown in FIGS. 18A, 18B and 18C, respectively, after removing the etch stop layer and the second semiconductor layer of the substrate, and forming a first backside ILD layer.

FIGS. 20A, 20B and 20C are cross sectional views of the exemplary semiconductor structure shown in FIGS. 19A, 19B and 19C, respectively, after replacing each backside source/drain contact placeholder structure with a backside source/drain contact structure.

FIGS. 21A, 21B and 21C are cross sectional views of the exemplary semiconductor structure shown in FIGS. 20A, 19B and 19C, respectively, after forming an additional backside ILD layer, forming backside power rail structures, and a backside interconnect structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the present application, a semiconductor device is described and illustrated as containing nanosheet transistors. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. A nanosheet FET is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology.

In the present application, the semiconductor device includes a frontside and a backside. The frontside includes a side of the device that includes at least one nanosheet transistor, frontside contact structures, and a frontside BEOL structure. The backside of the semiconductor device is the side of the device that is opposite the frontside. The backside includes a backside contact structure, and a backside interconnect structure.

In the present application, the semiconductor device includes at least one pair of cells, each cell including a complementary and symmetrical pair of p-type FETs (PFETs) and n-type FETS (NFETs) for logic functions. The cells can be referred to herein as complementary metal oxide semiconductor (CMOS) cells. CMOS technology can be used for constructing integrated circuit (IC) chips, including microprocessors, microcontrollers, memory chips and other digital logic circuits. CMOS technology can also be used for analog circuits such as image sensors, data converters, RF circuits and highly integrated transceivers for many types of communication.

In the present application, the semiconductor device is made by a process that eliminates active area module, shallow trench isolation module and gate module. The elimination of these modules makes the process of forming the NS-FETs of the inventive semiconductor device much easier and with cost savings.

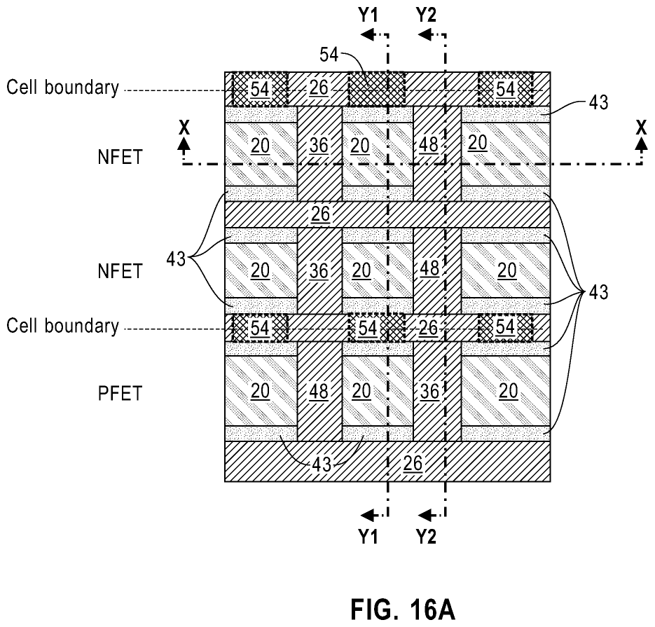

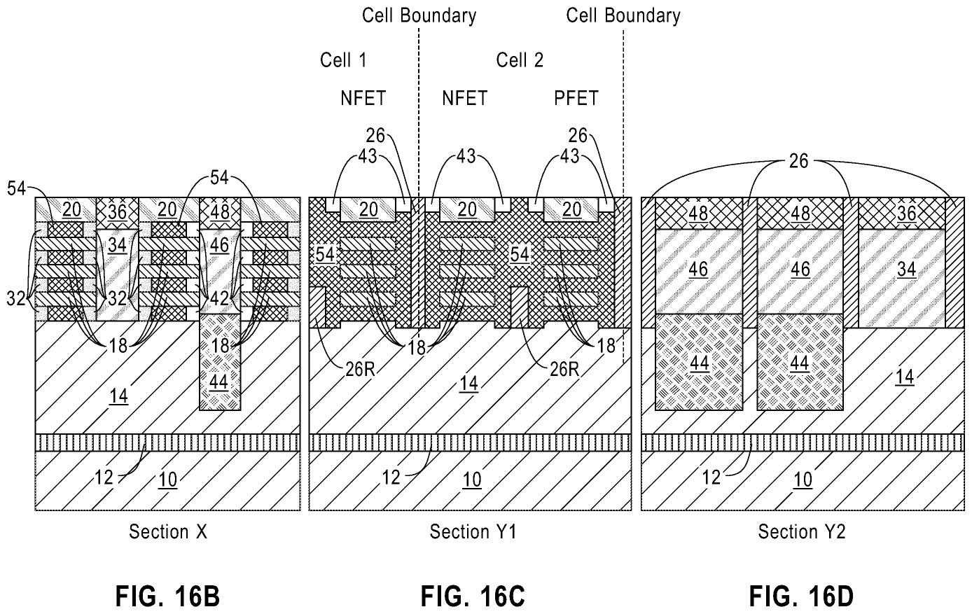

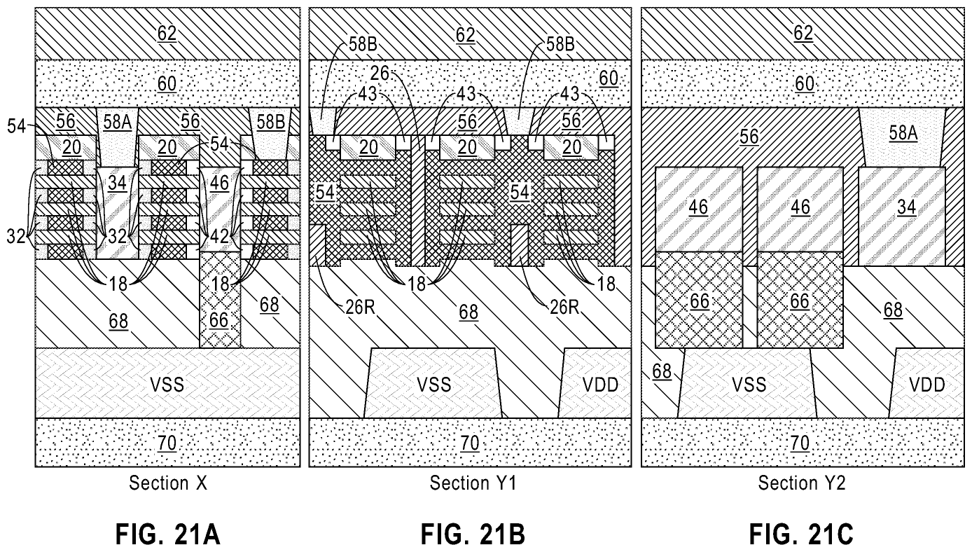

Notably and as is illustrated in FIGS. 16-16D (frontside only) and FIGS. 21A-21C (frontside and backside), the semiconductor device of the present application includes a first CMOS cell, Cell 1, including a first pair of complementary nanosheet field effect transistors (NS-FETs) including a first shared gate structure (i.e., gate structure 54) and a second CMOS cell, Cell 2, including a second pair of complementary NS-FETs including a second shared gate structure (i.e., gate structure 54). The device further includes a first dielectric material pillar (i.e., dielectric material pillar 26) having a first height separating the first shared gate structure of Cell 1 from the second shared gate structure of Cell 2, and a second dielectric material pillar (i.e., recessed dielectric material pillar 26R) having a second height that is less than the first height, wherein the second dielectric material pillar is located between the complementary NS-FETs of both the first pair of complementary NS-FETs and the second pair of complementary NS-FETs. The device even further includes a hard mask cap 20 located above each of the complementary NS-FETs of both the first pair of complementary NS-FETs and the second pair of complementary NS-FETs, wherein the hard mask cap 20 has outermost edges that are substantially vertically aligned to outermost edges of each semiconductor channel material nanosheet 18 of the complementary NS-FETs of the first pair of complementary NS-FETs and the second pair of complementary NS-FETs in a direction perpendicular to both the first shared gate structure and the second shared gate structure (See, for example, FIG. 21B), and the hard mask cap 20 extends horizontally beyond each semiconductor channel material nanosheet 18 of the complementary NS-FETs of the first pair of complementary NS-FETs and the second pair of complementary NS-FETs in a direction parallel to the both the first shared gate structure and the second shared gate structure (See, for example, FIG. 21A). The device yet further includes a dielectric material cap (e.g., second dielectric material cap 43 shown in FIG. 21B) extending outward from each of the outermost edges of the hard mask cap 20 in the direction parallel to the both the first shared gate structure and the second shared gate structure. In embodiments, the dielectric material cap can be a first dielectric material cap 33. The formation of the hard mask cap 20 and the dielectric material cap (e.g., second dielectric material cap 43 shown in FIG. 21B) helps in defining the gate region and gate extension region of each shared gate structure without a need to have an active area mask, and keeps the shared gate structures sealed during source/drain epi formation.

In embodiments of the present application, the dielectric material cap (e.g., second dielectric material cap 43 shown in FIG. 21B) has a topmost surface that is substantially coplanar with a topmost surface of the hard mask cap 20 and a bottommost surface that is vertically offset, and located above, a bottommost surface of the hard mask cap 20. The dielectric material cap of the present application is located over a channel region of each shared gate structure. This allows for accurately defining the active area width and protecting the active area from being exposed during S/D formation.

In embodiments of the present application, the dielectric material cap (e.g., second dielectric material cap 43 shown in FIG. 21B) has a first sidewall contacting one of the outermost sidewalls of the hard mask cap 20 and a second sidewall contacting a sidewall of the first dielectric material pillar (i.e., dielectric material pillar 26) that separates the first CMOS cell from the second CMOS cell. This aspect of the present application accurately defines the gate extension size and sealing the sacrificial gates when S/D epitaxy is grown.

In embodiments of the present application, each of the first shared gate structure, the second shared gate structure, the first dielectric material pillar (i.e., dielectric material pillar 26) and the second dielectric material pillar (i.e., recessed dielectric material pillar 26R) is located directly on a surface of a backside interlayer dielectric (ILD) material of a backside ILD structure 68. This aspect of the present application allows for the elimination of the shallow trench isolation module which helps to make the processing easier and helps to mitigate production costs.

In embodiments of the present application, each complementary NS-FET of the first pair of complementary NS-FETs and the second pair of complementary NS-FET has a first type S/D region 34 and a second type S/D region 36.

In embodiments of the present application, the device can further include first inner spacers 32 located adjacent to the first type S/D region 34, and second inner spacers 42 located adjacent to the second type S/D region 46, wherein the first inner spacers 32 are composed of a first spacer dielectric material having a first dielectric constant and the second inner spacers 42 are composed of a second spacer dielectric material having a second dielectric constant which differs from the first dielectric constant. The different types of inner spacers provide optimized capacitance for both source side and drain side.

In embodiments of the present application, the second dielectric constant is less than the first dielectric constant.

In embodiments of the present application, the first type S/D region 34 is a drain region, and the second type S/D region 36 is a source region. In other embodiments, the opposite is contemplated.

In some embodiments of the present application, the dielectric material cap (e.g., second dielectric material cap 43 shown in FIG. 21B) is composed of the second spacer dielectric material. In other embodiments, the dielectric cap (e.g., first dielectric material cap 33) is composed of the first spacer dielectric material.

In embodiments of the present application, the device can further include a frontside BEOL structure 60 electrically connected to the first type S/D region 34 by a frontside source/drain contact structure 58A. This aspect of the present application provides electrically contact of the source/drain region of NS-FETs to the frontside BEOL structure 60.

In embodiments of the present application, the device can further include a frontside gate contact structure 58B electrically connecting each of the first shared gate structure and the second shared gate structure to the frontside BEOL structure 60. This aspect of the present application provides electrically contact of the shared gate structures of NS-FETs to the frontside BEOL structure 60.

In embodiments of the present application, the frontside gate contact structure 58B is located above the second dielectric material pillar (i.e., recessed dielectric material pillar 24R) and is in contact with at least a portion of the topmost surface of the dielectric material cap (e.g., second dielectric material cap 43 shown in FIG. 21B.

In embodiments of the present application, the device can further include a carrier wafer 62 located on the frontside BEOL structure 60. The carrier wafer 62 allows for backside processing to occur.

In embodiments of the present application, the device can further include a VSS power rail electrically connected to the second type S/D region 46 by a backside frontside source/drain contact structure 66. This aspect of the present application provides electrically contact of the source/drain region of NS-FETs to the a backside power rail, i.e., the VSS power rail.

In embodiments of the present application, the device can further include a backside interconnect structure 70 located on a surface of the backside VSS power rail. The backside interconnect structure 70 can be used in the present application as a backside power distribution network.

In embodiments of the present application, the device can further include a backside VDD power rail spaced apart from the backside VSS power rail and located on the backside interconnect structure 70.

In embodiments of the present application (See, for example, FIG. 21A), and in the direction parallel to the both the first shared gate structure and the second shared gate structure, an outermost edge of each of the first inner spacers 32 are substantially vertically aligned to one of the outermost edges of the hard mask cap 20 and an outermost edge of each of the second inner spacers 42 are substantially vertically aligned to another of the outermost edges of the hard mask cap 20.

In embodiments of the present application, the first dielectric material pillar (i.e., dielectric material pillar 26) has a topmost surface that is substantially coplanar with a topmost surface of the dielectric material cap (e.g., second dielectric material cap 43 shown in FIG. 21B) and a topmost surface of the hard mask cap 20.

In embodiments of the present application, the first dielectric material pillar (i.e., dielectric material pillar 26) and the second dielectric material pillar (i.e., recessed dielectric material pillar 26R) are each composed of a same interlayer dielectric material.

These and other aspects of the present application will now be described in greater detail.

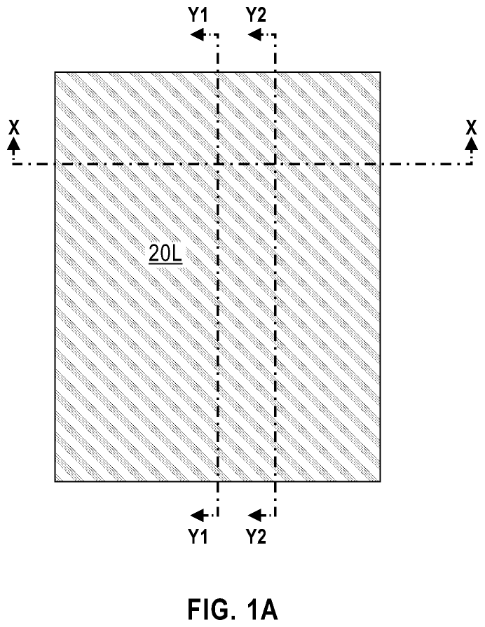

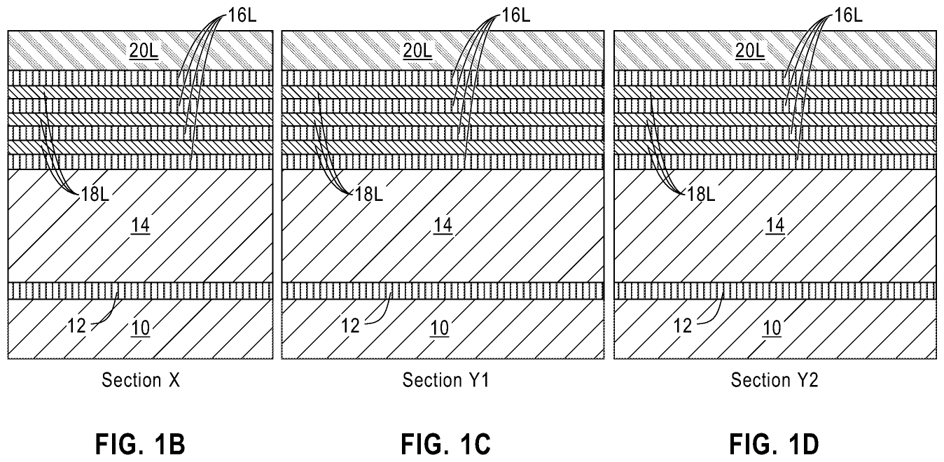

Reference is first made to FIGS. 1A-1D which illustrate various views of an exemplary semiconductor structure that can be employed in the present application. FIG. 1A is a top down view that includes cuts X-X, Y1-Y1 and Y2-Y1. In the present application, cut X-X is through one of the device areas of the exemplary structure, Cut Y1-Y1, which is perpendicular to X-X, is through the gate region of three separate device areas. Cut Y2-Y2, which is parallel to Y1-Y1, yet perpendicular to X-X, is in the source/drain regions of the three separate device regions. In the present application, and by way of one example, the first and second device regions are regions in which NFETs will be formed, while the third device is a region in which PFETs will be formed. This aspect of the present application will be become more apparent in subsequent processing steps of the present application.

The exemplary semiconductor structure illustrated in FIGS. 1A-1D includes a material stack located on a substrate, and a hard mask layer 20L located on the material stack. In the present application, the substrate can include a first semiconductor layer 10, an etch stop layer 12 and a second semiconductor layer 14. In embodiments, the first semiconductor layer 10 and/or the etch stop layer 12 can be omitted from the substrate. The material stack of the illustrated exemplary semiconductor structure includes alternating sacrificial semiconductor material layers 16L and semiconductor channel material layers 18L. Each of the element/components of the exemplary semiconductor structure illustrated in FIGS. 1A-1D will now be described in greater detail.

The first semiconductor layer 10 is composed of a first semiconductor material, and the second semiconductor layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor layer 14 can be compositionally the same as, or compositionally different from, the first semiconductor material that provides the first semiconductor layer 10.

In some embodiments of the present application, the etch stop layer 12 can be composed of a dielectric material such as, for example, silicon dioxide and/or boron nitride. In other embodiments of the present application, the etch stop layer 12 is composed of a semiconductor material that is compositionally different from the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon.

The substrate including the first semiconductor layer 10, the etch stop layer 12 and the second semiconductor layer 14 can be formed utilizing techniques well known to those skilled in the art. For example, the substrate including the first semiconductor layer 10, the etch stop layer 12 and the second semiconductor layer 14 can be formed by a separation by ion implantation of oxygen process, or wafer bonding. Alternatively, the substrate including the first semiconductor layer 10, the etch stop layer 12 and the second semiconductor layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

As mentioned above, the material stack includes alternating sacrificial semiconductor material layers 16L and semiconductor channel material layers 18L. In some embodiments and as is illustrated in FIGS. 1B-1D, the material stack can include ‘n’ number of semiconductor channel material layers 18L and ‘n+1’ number of sacrificial semiconductor material layers 16L, wherein n is an integer greater than one. By way of one example, the material stack can include four sacrificial semiconductor material layers 16L and three semiconductor channel material layers 18L. In the illustrated material stack, each semiconductor channel material layer 18L is sandwiched between a bottom sacrificial semiconductor material layer and a top sacrificial semiconductor material layer. Although not illustrated, embodiments exist in which the material stack includes an equal number of sacrificial semiconductor material layers 16L and semiconductor channel material layers 18L. Each sacrificial semiconductor material layer 16L is composed of a third semiconductor material, while each semiconductor channel material layer 18L is composed of a fourth semiconductor material that is compositionally different from the third semiconductor material. In some embodiments, the fourth semiconductor material that provides each semiconductor channel material layer 18L can provide high channel mobility for n-type FET devices (i.e., NFETs). In other embodiments, the fourth semiconductor material that provides each semiconductor channel material layer 18L can provide high channel mobility for p-type FET devices (PFETs). The third semiconductor material that provides each sacrificial semiconductor material layer 16L, and the fourth semiconductor material that provides each semiconductor channel material layer 18L can include one of the semiconductor materials mentioned above. In one example, the third semiconductor material that provides each sacrificial semiconductor material layer 16L is composed of a silicon germanium alloy having a germanium content from 20 atomic percent to 40 atomic percent and the fourth semiconductor material that provides each semiconductor channel material layer 18L is composed of silicon. Other combinations of semiconductor materials are possible as long as the third semiconductor material that provides each sacrificial semiconductor material layer 16L is compositionally different from the fourth semiconductor material that provides each semiconductor channel material layer 18L.

The material stack including the alternating sacrificial semiconductor material layers 16Land semiconductor channel material layers 18L can be formed by CVD, PECVD, epitaxial growth or any combination of such deposition processes.

The hard mask layer 20L which is formed on the uppermost (i.e., topmost) surface of the material stack, is composed of any dielectric hard mask material such as, for example, silicon nitride, silicon oxide, and/or silicon oxynitride. The hard mask layer 20L can be formed by a deposition process such as, for example, CVD, PECVD, physical vapor deposition (PVD) or atomic layer deposition (ALD).

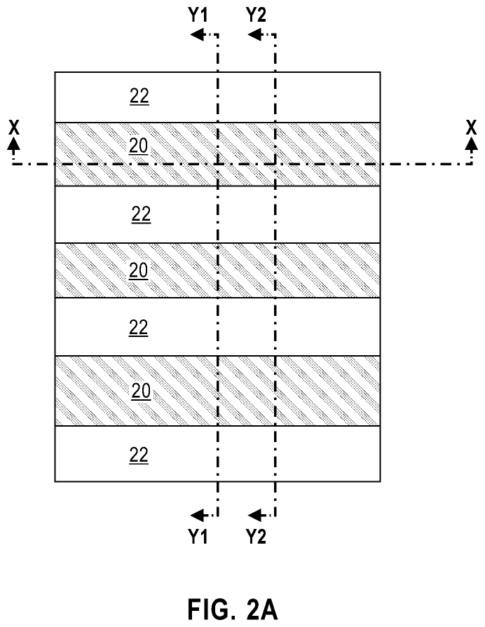

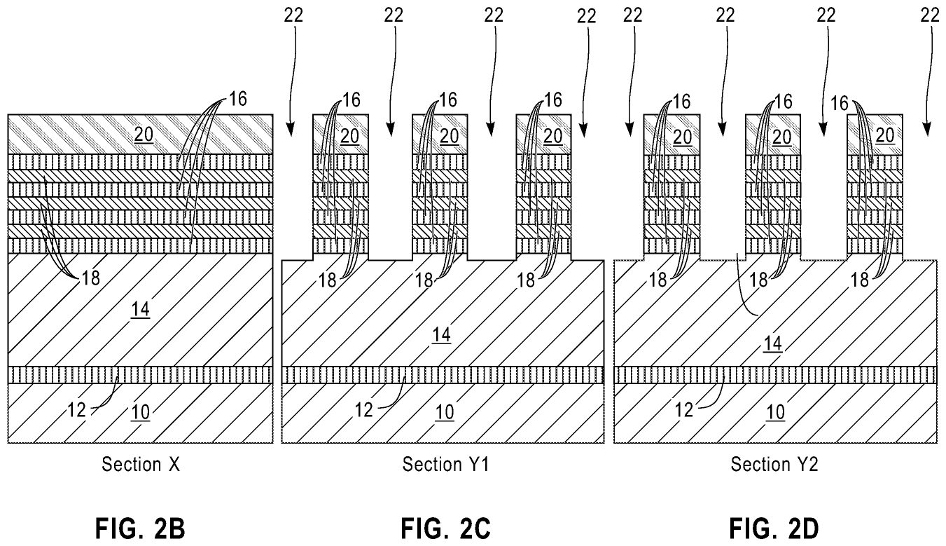

Referring now to FIGS. 2A-2D, there are illustrated the exemplary semiconductor structure shown in FIGS. 1A-1D, respectively, after gate cut patterning. Gate cut patterning includes lithography and etching. Lithography includes forming a photoresist material on a layer or stack of material layers that need to be patterned, exposing the photoresist material to a desired pattern of irradiation and thereafter developing the exposed photoresist material utilizing a conventional resist developer. The developed photoresist material has a desired pattern (i.e., gate patterned) that is then transferred to the layer or stack of material layers that need to be patterned by etching. Etching can include dry etching and/or chemical wet etching. In one embodiment, a dry etch such as, for example, reactive ion etching (RIE), ion beam etching (IBE), plasma etching or any combination thereof can be used to transfer the pattern to the layer or stack of material layers that need to be patterned. In illustrated embodiment, this etch etches through an entirety of the hard mask layer 20L and an entirety of the material stack and stops on a surface of the second semiconductor layer 14. In embodiments, this etch can remove a portion of the second semiconductor layer 14. The developed photoresist material can be removed any time after etching (including an initial etch or the entirety of the etch) utilizing a conventional photoresist removal process. In conventional CMOS fabrication process, several critical modules are done before gate cut module, such as active region patterning, STI formation, gate patterning, etc. In the present application, those modules are completely removed, which results in greatly saved fabrication cost.

After performing this gate cut patterning steps, nanosheet stacks (three are shown by way of one example in FIGS. 2C and 2D) that are capped with a remaining, i.e., non-etched portion of the hard mask layer 20L are provided. The remaining, i.e., non-etch, portion of the hard mask layer 20L can be referred to herein as a hard mask cap 20. The hard mask cap 20 will be subsequently used in the present application as a gate cap. The number of nanosheet stacks can vary and is not limited to the number illustrated in the drawings of the present application. Each nanosheet stack includes a remaining, i.e., non-etched, portion of the material stack. That is, each nanosheet stack includes non-etched portions of the alternating sacrificial semiconductor material layers 16L and the semiconductor channel material layers 18L. In the present application, each remaining, i.e., non-etched, portion of the sacrificial semiconductor material layers 16L can be referred to as a sacrificial semiconductor material nanosheet 16, and each remaining, i.e., non-etched, portion of the remaining, i.e., non-etched, portion of the semiconductor channel material layers 18L can be referred to as a semiconductor channel material nanosheet 18. Thus, each nanosheet stack including alternating sacrificial semiconductor material nanosheets 16 and semiconductor channel material nanosheets 18. Each nanosheet stack can be located on a non-etched, i.e., mesa, portion of the second semiconductor layer 14.

At this point of the present application, the sacrificial semiconductor material nanosheets 16 and the semiconductor channel material nanosheets 18 have a same length and width. In embodiments, the width of each of the sacrificial semiconductor material nanosheet 16 and each semiconductor channel material nanosheet 18 is from 6 nm to 100 m. Other widths can be used in the present application for the width of each sacrificial semiconductor material nanosheet 16 and each semiconductor channel material nanosheet 18. The height of the sacrificial semiconductor material nanosheets 16 can be the same or different from the height of the semiconductor channel material nanosheets 18. Further processing will reduce the length and/or width of the nanosheets within each nanosheet stack.

In the present application, each of the nanosheet stacks that are capped with the hard mask cap 20 are spaced apart by a gap 22 as is shown in FIGS. 2C and 2D. In the illustrated embodiments, the three nanosheet stacks are in the different device regions as mentioned above.

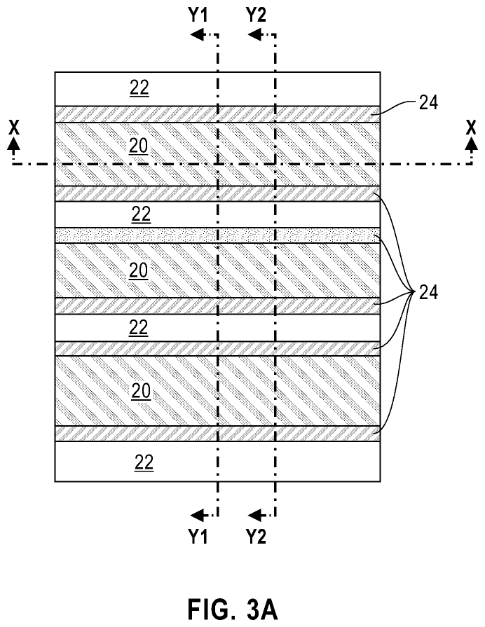

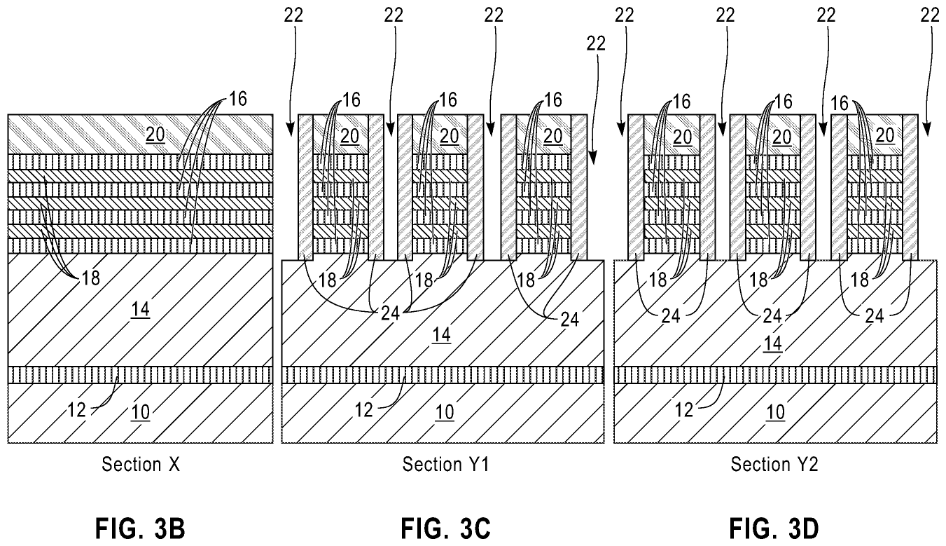

Referring now to FIGS. 3A-3D, there are illustrated the exemplary semiconductor structure shown in FIGS. 2A-2D, respectively, after forming a sacrificial spacer 24. The sacrificial spacer 24 is composed of the third semiconductor material as mentioned above for each sacrificial semiconductor material layer 16L. Thus, sacrificial spacer 24 and the sacrificial semiconductor material layers 16L are composed of a compositionally same semiconductor material. In one embodiment, when each sacrificial semiconductor material layer 16L is composed of a silicon germanium alloy having a germanium content from 20 atomic percent to 40 atomic percent, then the sacrificial spacer 24 is also composed of the compositionally same silicon germanium alloy. Since the sacrificial spacer 24 and the sacrificial semiconductor material layers 16L are composed of the same third semiconductor material, the sacrificial spacer 24 and the sacrificial semiconductor material layers 16L have a same etch rate and can be removed simultaneously during the formation of the gate structure.

The sacrificial spacer 24 is present along the sidewall of each hard mask capped nanosheet stack and is present in gap 22. In embodiments in which the nanosheet stacks sit on top of a mesa portion (i.e., non-etched portion) of the second semiconductor layer 14, the sacrificial spacer 24 is also present along the sidewall of the mesa portion of the second semiconductor layer 14. The sacrificial spacer 24 has a topmost surface that is substantially coplanar with a topmost surface of the hard mask cap 20. The sacrificial spacer 24 can be formed by deposition of the third semiconductor material, followed by a spacer etch.

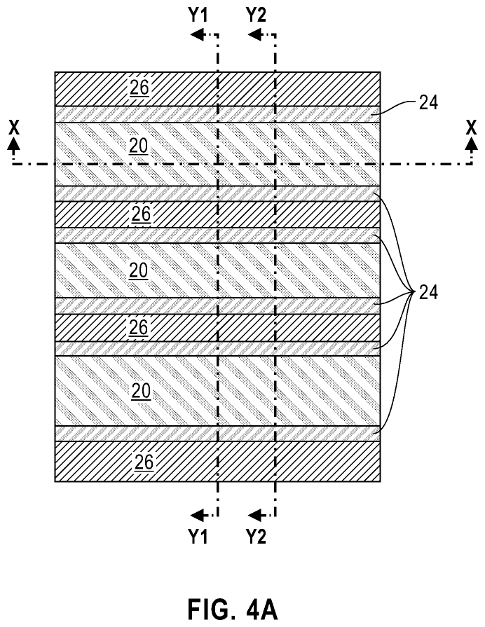

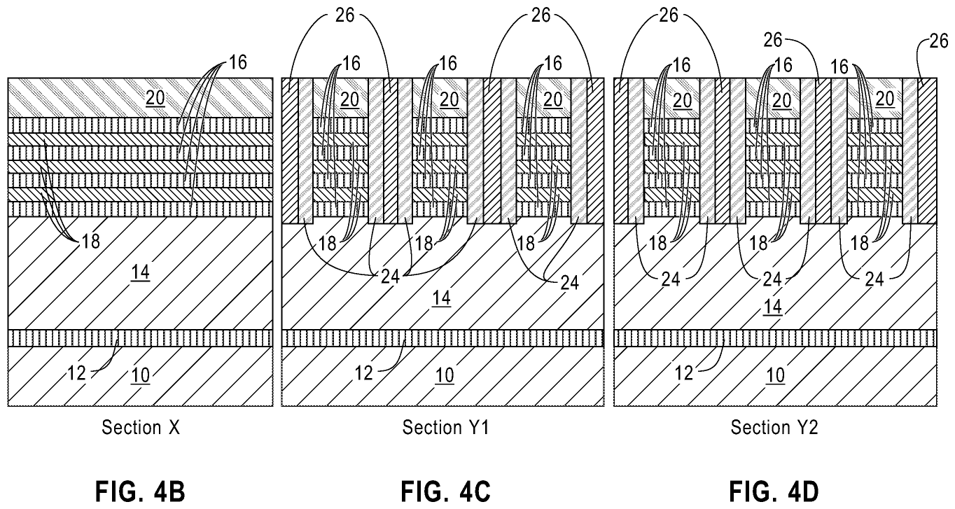

Referring now to FIGS. 4A-4D, there are illustrated the exemplary semiconductor structure shown in FIGS. 3A-3D, respectively, after forming a dielectric material pillar 26 adjacent to each sacrificial spacer 24. The dielectric material pillar 26 fills in a remaining volume of the gap 22 and is present along a sidewall of the sacrificial spacer 24. In the illustrated embodiment shown in FIG. 4C, the dielectric material pillar 26 separates the nanosheet stacks in different device regions from each other. The dielectric material pillar 26 is composed of a dielectric material which is typically compositionally different from the dielectric hard mask material. The dielectric material that provides the dielectric pillar 26 can be composed of, for example, an ILD material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted). The dielectric material pillar 26 can be formed by deposition of the dielectric material (CVD, PECVD or spin-on coating), followed by a planarization process. Planarization can include chemical mechanical polishing (CMP) and/or grinding. The dielectric pillar 26 has a topmost surface that is substantially coplanar with a topmost surface of the sacrificial spacer 24 and a topmost surface of the hard mask cap 20. The dielectric material pillar 26 can also be composed of dielectric materials, such as, for example, SiBCN, SiOCN, SiCO, or SiC.

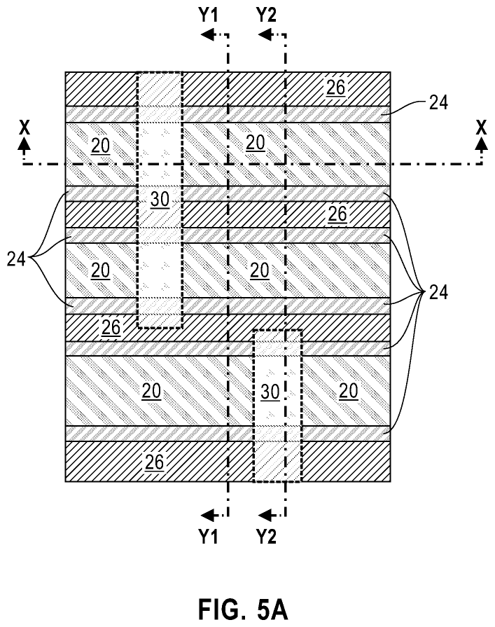

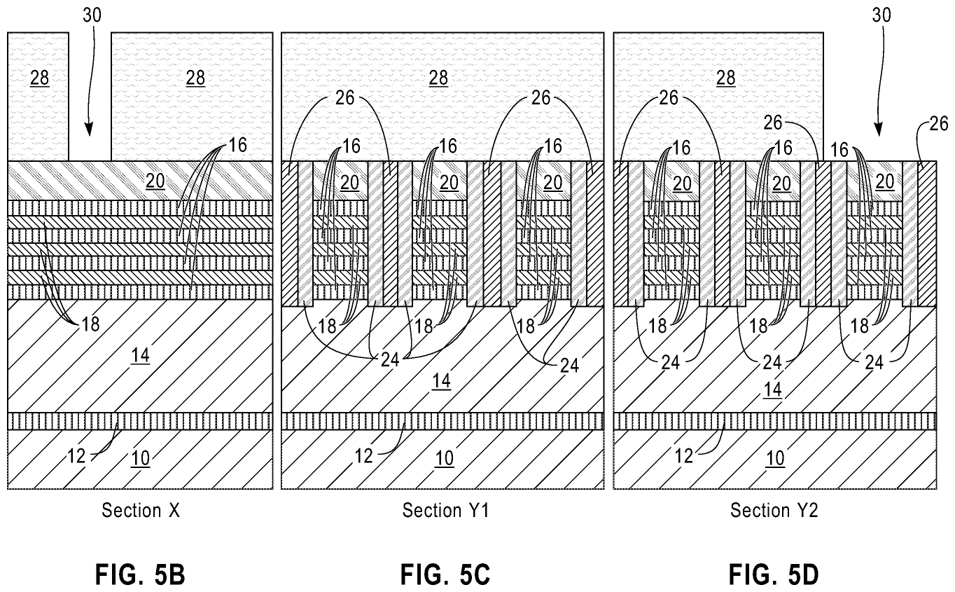

Referring now to FIGS. 5A-5D, there are illustrated the exemplary semiconductor structure shown in FIGS. 4A-4D, respectively, after first S/D type patterning; throughout the present application the term “S/D” refers to source/drain. The first S/D type patterning includes forming an organic planarization layer (OPL) on the exemplary structure shown in FIGS. 4A-4D. The OPL can be formed by a deposition process such as, for example, CVD, PECVD or spin-on coating. The OPL is the patterned by lithography and etching to provide patterned OPL 28 having openings 30 formed therein. The patterned OPL 28 is not shown in FIG. 5A for clarity. The etch can include a dry etching process such as, for example, RIE. The openings 30 physically expose a portion of the hard mask cap 20 that is present in the different device regions. In the illustrated embodiment, two openings 30 are shown by way of one example.

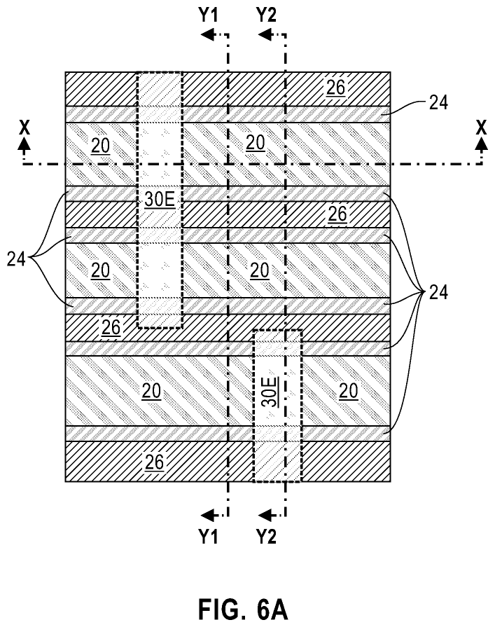

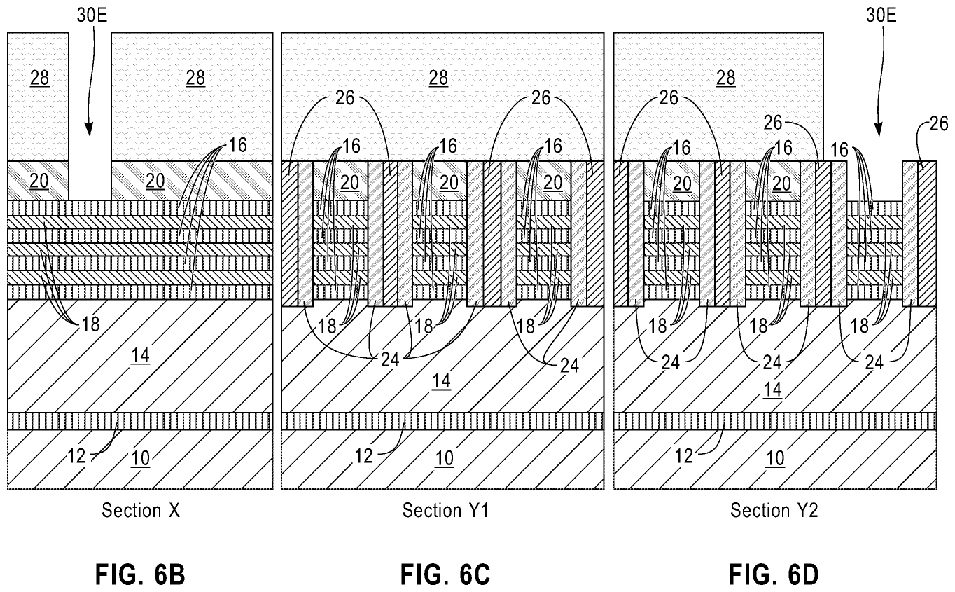

Referring now to FIGS. 6A-6D, there are illustrated the exemplary semiconductor structure shown in FIGS. 5A-5D, respectively, after selective hard mask cap removal. The selective hard mask cap removal utilizes the patterned OPL 28 as an etch mask and another etch that is selective in removing the physically exposed potion of the hard mask cap 20 is employed. This etch can include a dry etching process such as, for example, RIE, that is selective in removing hard mask material. This etch stops on the uppermost surface of the nanosheet stacks and extends each opening 30 forming extended openings 30E. Extending openings 30E physically expose an uppermost surface, i.e., a topmost sacrificial semiconductor material nanosheet, of the nanosheet stacks.

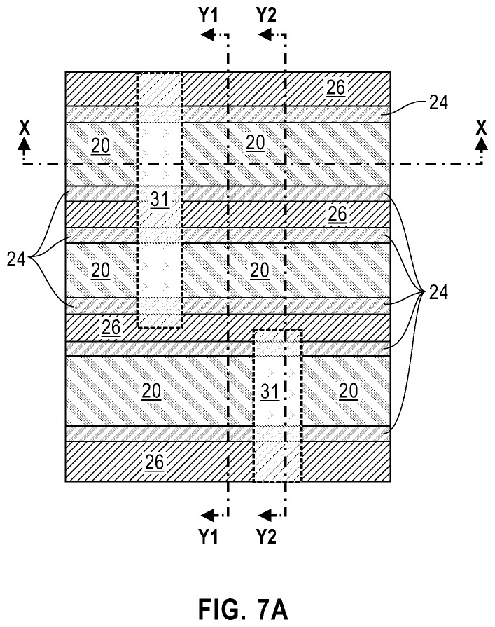

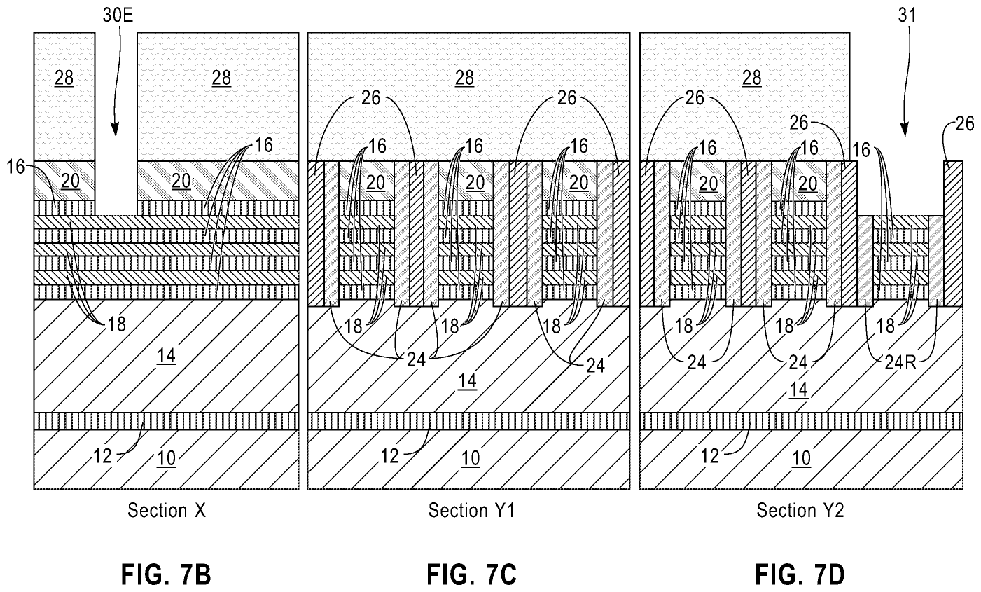

Referring now to FIGS. 7A-7D, there are illustrated the exemplary semiconductor structure shown in FIGS. 6A-6D, respectively, after selective sacrificial semiconductor material nanosheet removal. The selective sacrificial semiconductor material nanosheet removal utilizes the patterned OPL 28 as an etch mask and another etch that is selective in removing the physically exposed potion of the topmost sacrificial semiconductor material nanosheet of the nanosheet stack is employed. This etch can include a dry etching process such as, for example, RIE, that is selective in removing the third semiconductor material that provides the sacrificial semiconductor material nanosheets. This etch stops on a surface of an uppermost semiconductor channel material nanosheet and extends each extended opening 30E forming first type S/D openings 31. First type S/D openings 31 are employed in the present application in forming first type S/D regions. In the present application, each first type S/D region can be either a drain region or a source region of a NS-FET of the present application. The first type S/D openings 31 physically expose the uppermost semiconductor channel material nanosheet of the nanosheet stacks as shown in FIGS. 7B and 7D.

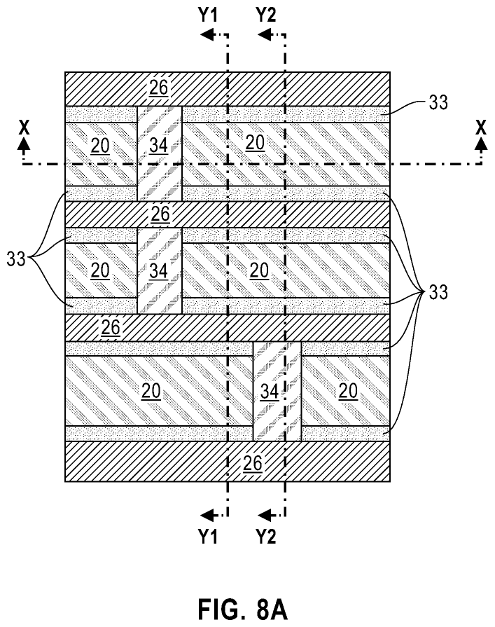

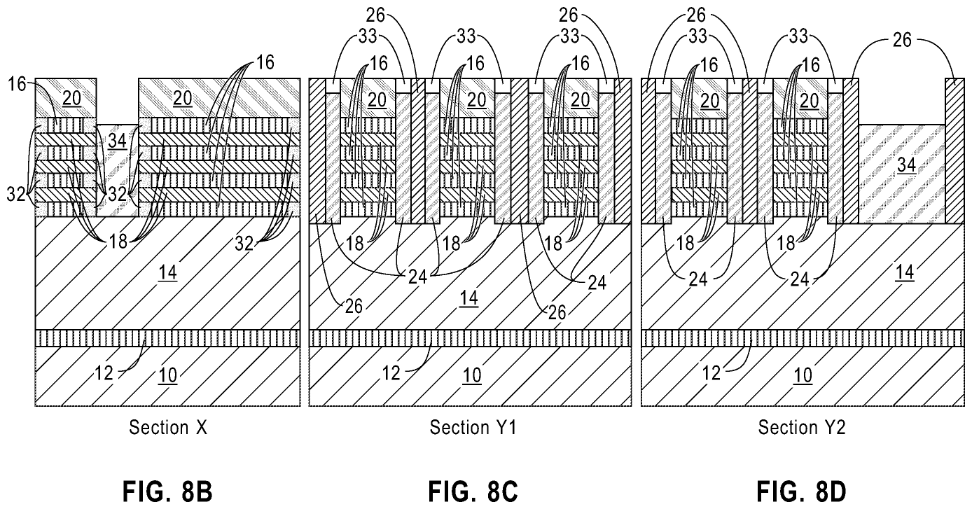

Referring now to FIGS. 8A-8D, there are illustrated the exemplary semiconductor structure shown in FIGS. 7A-7D, respectively, after nanosheet recessing, indentation of the sacrificial semiconductor material nanosheets 16, first inner spacer formation, and formation of a first type of source/drain region 34. The nanosheet recessing is performed through the first type S/D openings 31 and removes the remaining portion of the nanosheet stacks that are located directly beneath the first type S/D openings 31 and includes a recess etching process that is selective in removing the remaining portions of the nanosheet stacks that are directly beneath the first type S/D openings 31. The recess etch can include one or more etching processes. In one example, RIE is used to perform the nanosheet recessing. The nanosheet recessing stops on a surface of the second semiconductor layer 14.

After the nanosheet recessing, the patterned OPL 28 is removed from the surface of the exemplary structure utilizing a material removal process such as, for example, ashing. Next, the sacrificial semiconductor material nanosheets 16 that are physically exposed by the nanosheet recessing are subjected to an etching process that indents each of the sacrificial semiconductor material nanosheets 16. The etching process removes end portions of each of the sacrificial semiconductor material nanosheets 16 and forms a gap beneath and above each of the semiconductor channel material nanosheets 18. The sacrificial semiconductor material nanosheets 16 are now recessed and have a width that is less than the semiconductor channel material nanosheets 18. This etching process also removes an upper portion of each sacrificial spacer 24.

Next, a first inner spacer 32 is formed in each of the gaps and during the formation of the first inner spacer 32, a first dielectric material cap 33 is formed on top of each recessed sacrificial spacer 24. The first inner spacer 32 and the first dielectric material cap 33 are both composed of a first spacer dielectric material that has a first dielectric constant, k1. In some embodiments, the first dielectric constant, k1, is less than 4.0. Exemplary first dielectric spacer materials include, but are not limited to, SiBCN, SiOCN or SiOC. The first inner spacer 32 and the first dielectric material cap 33 can be formed by deposition of the first spacer dielectric material, followed by an isotropic etching process. The first inner spacer 32 that is formed in each gap is direct physical contact with an end portion of the recessed sacrificial semiconductor material nanosheets 16. These gap filling first inner spacers 32 have an outermost sidewall that is substantially vertically aligned to the outermost sidewall of each semiconductor channel material nanosheet 18. At this point of the present application, the first dielectric material cap 33 that is formed on top of the recessed sacrificial spacers 24 has a first sidewall that contacts a sidewall of the hard mask cap 20 and a second sidewall that contacts a sidewall of the dielectric material pillar 26. The first dielectric material cap 33 that is formed on top of the recessed sacrificial spacers 24 blocks the surface of the recessed sacrificial spacer 24 from being available during subsequent formation of the first type S/D region 34.

The first type S/D region 34 is typically formed by an epitaxial growth process, as defined above. A recess etch can follow the epitaxial growth process. The first type S/D region 34 extends outward from a physically exposed sidewall of each semiconductor channel material nanosheet 18 and upward from the second semiconductor layer 14. The first type S/D region 34 is composed of a fifth semiconductor material and a dopant. As used herein, a “source/drain” or “S/D” region can be a source region or a drain region depending on subsequent wiring and application of voltages during operation of the transistor. The fifth semiconductor material that provides first type S/D region 34 can be compositionally the same, or compositionally different from, the fourth semiconductor material that provides each semiconductor channel material nanosheet 18. The dopant that is present in the first type S/D region 34 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the first type S/D region 34 can have a dopant concentration of from 4×10²⁰ atoms/cm³ to 3×10²¹ atoms/cm³.

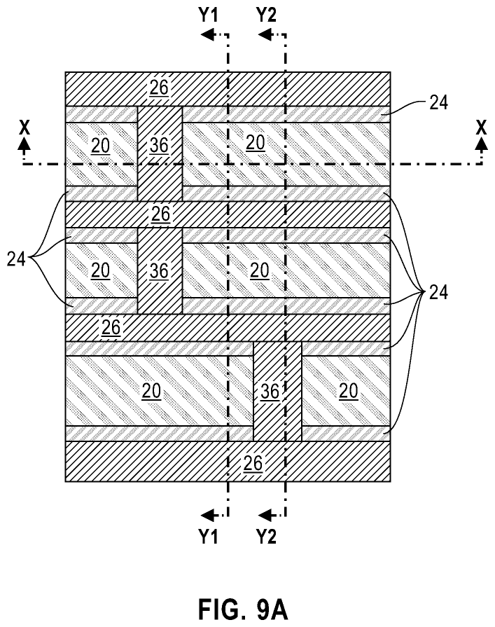

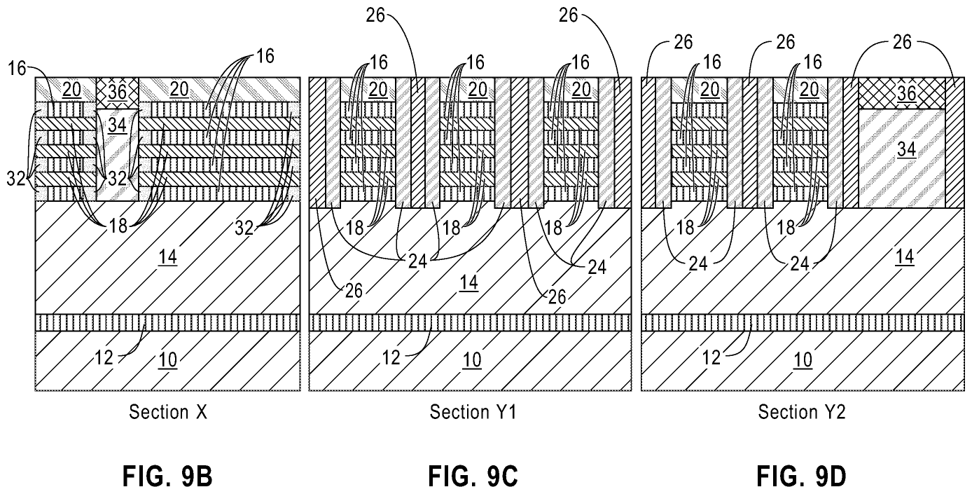

Referring now to FIGS. 9A-9D, there are illustrated the exemplary semiconductor structure shown in FIGS. 8A-8D, respectively, after forming a first frontside ILD layer 36. The first frontside ILD layer 36 is composed of one of the ILD materials mentioned above for the dielectric material pillar 26. The first frontside ILD layer 36 can be composed of a compositionally same, or compositionally different ILD material than the ILD material that provides the dielectric material pillar 26. The first frontside ILD layer 36 can be formed by a deposition process including, but not limited to, CVD, PECVD or spin-on coating. A planarization process such as, for example, CMP, can follow the deposition of the ILD material. During the planarization process that forms the first ILD material, the first dielectric material cap 33 that is formed on top of each of the recessed sacrificial spacers 24 is removed. The first frontside ILD layer 36 has a topmost surface that is substantially coplanar with a topmost surface of the hard mask cap 20, a topmost surface of the dielectric material pillar 26 and a remaining portion of the sacrificial spacer 24. The first frontside ILD layer 36 is formed on top of an along sidewalls of the first type S/D region 34.

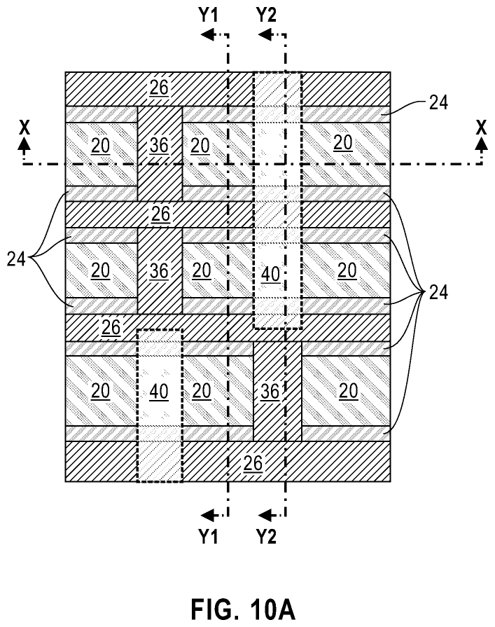

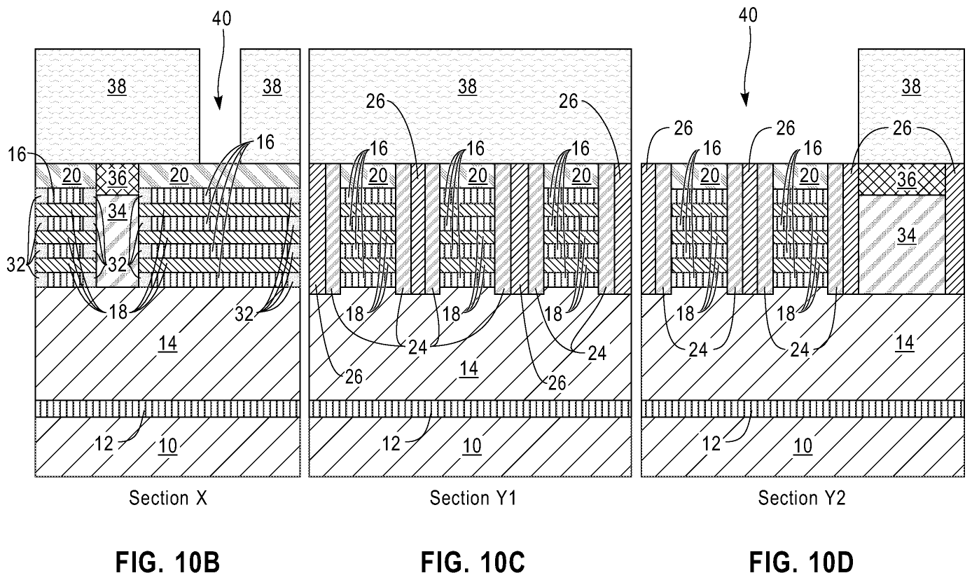

Referring now to FIGS. 10A-10D, there are illustrated the exemplary semiconductor structure shown in FIGS. 9A-9D, respectively, after second S/D type patterning. The second S/D type patterning includes forming another OPL on the exemplary structure shown in FIGS. 9A-9D. This another OPL can be formed by a deposition process such as, for example, CVD, PECVD or spin-on coating. This another OPL is the patterned by lithography and etching to provide patterned OPL 38 having openings 40 formed therein. Patterned OPL 38 is not shown in FIG. 10A for clarity. The etch can include a dry etching process such as, for example, RIE. The openings 40 physically expose a portion of the hard mask cap 20 that is present in the different device regions. In the illustrated embodiment, two openings 40 are shown by way of one example.

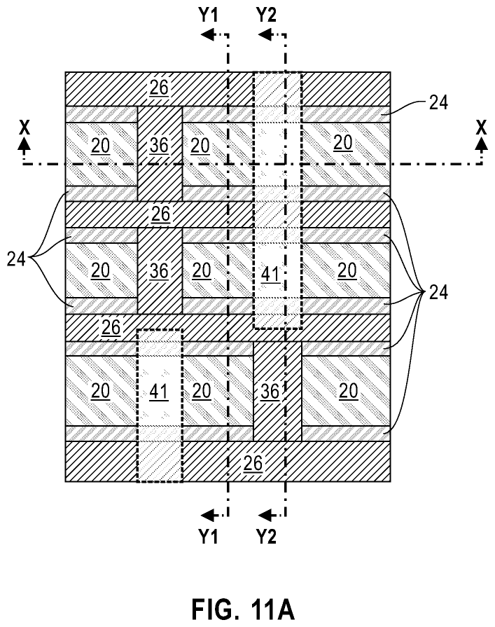

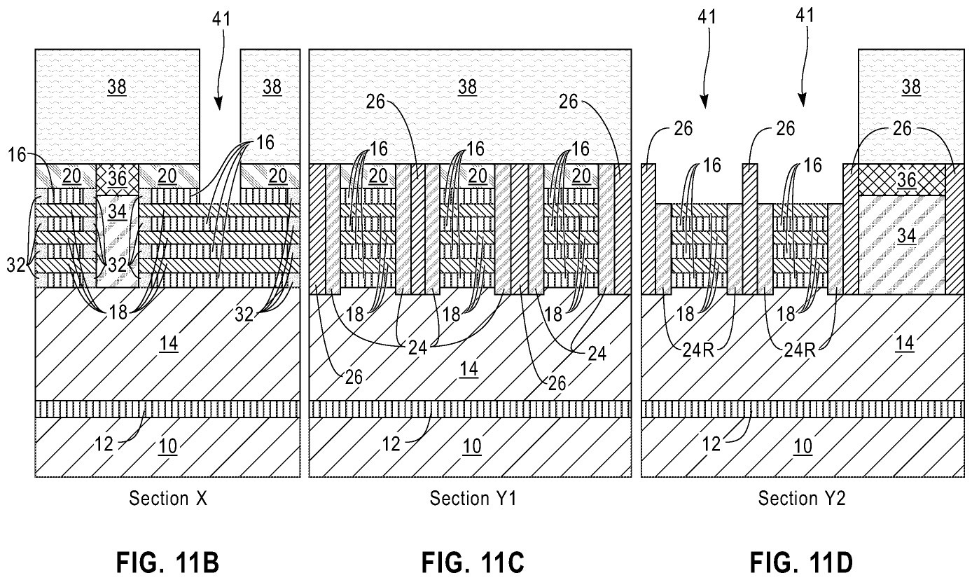

Referring now to FIGS. 11A-11D, there are illustrated the exemplary semiconductor structure shown in FIGS. 10A-10D, respectively, after selective hard mask cap removal and selective sacrificial semiconductor material layer removal. The selective hard mask cap removal utilizes patterned OPL 38 as an etch mask and another etch that is selective in removing the physically exposed potion of the hard mask cap 20 is employed. This etch can include a dry etching process such as, for example, RIE, that is selective in removing hard mask material. This etch stops on the uppermost surface of the nanosheet stacks and extends each opening 40 forming extended openings (not shown). The extending openings physically expose an uppermost surface, i.e., a topmost sacrificial semiconductor material nanosheet, of the nanosheet stacks.

The selective sacrificial semiconductor material nanosheet removal utilizes patterned OPL 38 as an etch mask and another etch that is selective in removing the physically exposed potion of the topmost sacrificial semiconductor material nanosheet of the nanosheet stack is employed. This etch can include a dry etching process such as, for example, RIE, that is selective in removing the third semiconductor material that provides the sacrificial semiconductor material nanosheets 16. This etch stops on a surface of an uppermost semiconductor channel material nanosheet and extends each extended opening forming second type S/D openings 41. Second type S/D openings 41 are employed in the present application in forming second type S/D regions. The second type S/D openings 41 physically expose the uppermost semiconductor channel material nanosheet of the nanosheet stacks as shown in FIGS. 11B and 11D. In the present application, each second type S/D region is the other of a source region or a drain region depending on whether the first type S/D region 34 is a source region or a drain region. In some embodiments, the first type S/D regions 34 are drain regions, and the second type S/D regions are source regions. In other embodiments, the first type S/D regions 34 are source regions, and the second type S/D regions are drain regions.

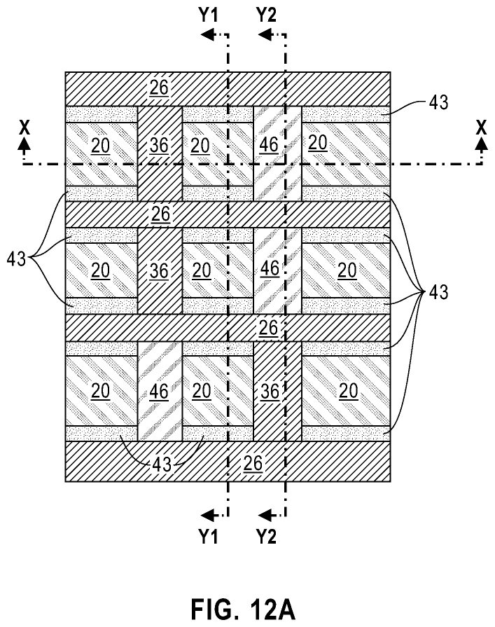

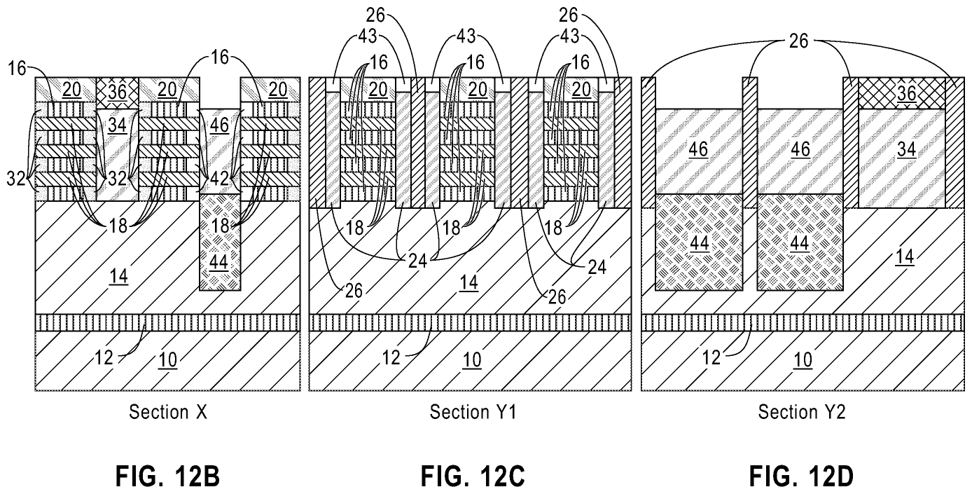

Referring now to FIGS. 12A-12D, there are illustrated the exemplary semiconductor structure shown in FIGS. 11A-11D, respectively, after nanosheet recessing, indentation of the sacrificial semiconductor material layers 16, second inner spacer formation, and formation of a backside source/drain contact placeholder structure 44 and a second type of source/drain region 46. The nanosheet recessing is performed through the second type S/D openings 41 and removes the remaining portion of the nanosheet stacks that are located directly beneath the second type S/D openings 41 and includes a recess etching process that is selective in removing the remaining portions of the nanosheet stacks that are directly beneath the second type S/D openings 41. The recess etch can include one or more etching processes. In one example, RIE is used to perform the nanosheet recessing. The nanosheet recessing stops on a sub-surface of the second semiconductor layer 14 and creates a cavity in the second semiconductor layer 14.

After nanosheet recessing, the patterned OPL 38 is removed from the surface of the exemplary structure utilizing a material removal process such as, for example, ashing. The sacrificial semiconductor material nanosheets 16 that are physically exposed by the nanosheet recessing are subjected to an etching process that indents each of the sacrificial semiconductor material nanosheets 16 is performed. The etching process removes end portions of each of the sacrificial semiconductor material nanosheets 16 and forms a gap beneath and above each of the semiconductor channel material nanosheets 18. The sacrificial semiconductor material nanosheets 16 are now recessed and have a width that is less than the semiconductor channel material nanosheets 18. This etching process also removes an upper portion of each sacrificial spacer 24.

Next, a second inner spacer 42 is formed in each of the gaps and a second dielectric material cap 43 is formed on top of each recessed sacrificial spacer 24. The second inner spacer 42 and the second dielectric material cap 43 are both composed of a second spacer dielectric material that has a second dielectric constant, k2. The second dielectric constant of the second dielectric spacer material can be equal to or different from the first dielectric constant of the first dielectric spacer material. In some embodiments, the second dielectric constant is greater than the first dielectric constant. In such embodiments, the second inner spacer 42 and the second dielectric material cap 43 can be composed of silicon oxide, silicon nitride or silicon oxynitride. The second dielectric spacer material that provides the second inner spacer 42 and the second dielectric material cap 43 is typically compositionally different from the hard mask material that provides hard mask cap 20. The second inner spacer 42 and the second dielectric material cap 43 can be formed by deposition of the first spacer dielectric material, followed by an isotropic etching process. The second inner spacer 42 that is formed in each gap is direct physical contact with an end portion of the recessed sacrificial semiconductor material nanosheets 16. These gap filling second inner spacers 42 have an outermost sidewall that is substantially vertically aligned to the outermost sidewall of each semiconductor channel material nanosheet 18. The second dielectric material cap 43 that is formed on top of the recessed sacrificial spacers 24 has a first sidewall that contacts a sidewall of the hard mask cap 20 and a second sidewall that contacts a sidewall of the dielectric material pillar 26 or a sidewall of the gate structure to be subsequently formed. The second dielectric material cap 43 that is formed on top of each recessed sacrificial spacer 24 blocks the surface of the recessed sacrificial spacer 24 from being available during subsequent formation of the second type S/D region 46.

Next, the backside source/drain contact placeholder structure 44 is formed into the cavity created above. The backside source/drain contact placeholder structure 44 is composed of a sixth semiconductor material which is compositionally different from the second semiconductor material that provides the second semiconductor layer 14. In one example, the backside source/drain contact placeholder structure 44 is composed of a silicon germanium alloy. The backside source/drain contact placeholder structure 44 can be formed by deposition (e.g., CVD, PECVD or epitaxial growth) of the sixth semiconductor material, followed by a recess etch. Note that the backside source/drain contact placeholder structure 44 can extend above the topmost surface of the second semiconductor layer 14, but the height of the backside source/drain contact placeholder structure 44 is less than the bottommost surface of the bottommost semiconductor channel material nanosheet of each nanosheet stack.

The second type S/D region 46 is typically formed by an epitaxial growth process, as defined above. A recess etch can follow the epitaxial growth process. The second type S/D region 46 extends outward from a physically exposed sidewall of each semiconductor channel material nanosheet 18 and upward from the backside source/drain contact placeholder structure 44. The second type S/D region 46 is composed of a seventh semiconductor material and a dopant. The seventh semiconductor material can be compositionally the same as, or compositionally different from the fifth semiconductor material that provides the first type S/D region 34. In the present application, the first type S/D region 34 can be a one of a source region or a drain region, and the second type S/D region 46 is the other of a source region or a drain region. In the present application, the first type S/D region 34 and the second type S/D region 46 can be used as the S/D regions of a single NS-FET. The dopant that is present in the second type S/D region 46 can be a same conductivity type as the dopant present in the first type S/D region 34. In one example, the second type S/D region 46 can have a dopant concentration of from 4×10²⁰ atoms/cm³ to 3×10²¹ atoms/cm³. In the present application, the first type S/D region 34 is located adjacent to the first inner spacers 32, and the second type S/D region 46 is located adjacent to the second inner spacers 42.

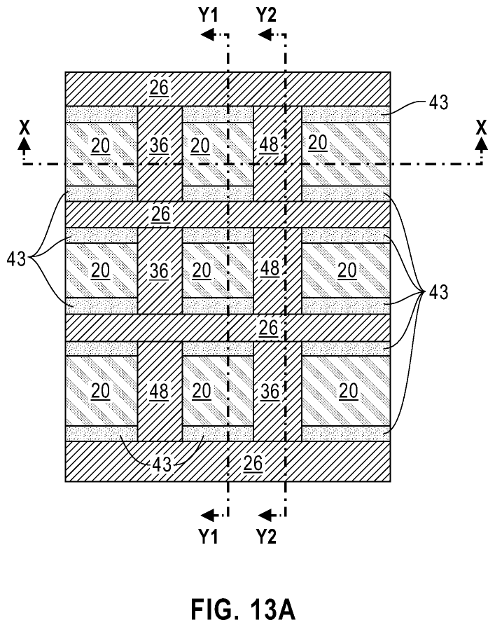

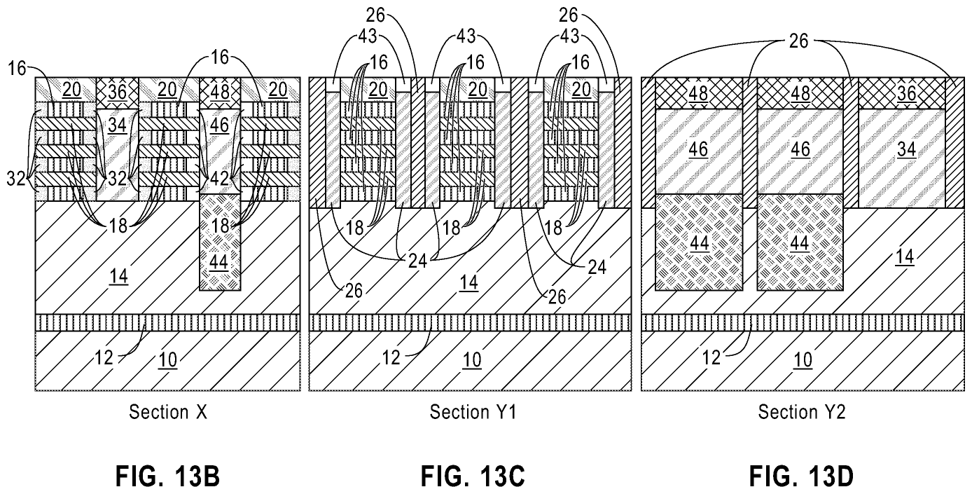

Referring now to FIGS. 13A-13D, there are illustrated the exemplary semiconductor structure shown in FIGS. 12A-12D, respectively, after forming a second frontside ILD layer 48. The second frontside ILD layer 48 is composed of one of the ILD materials mentioned above for the dielectric material pillar 26. The second frontside ILD layer 48 can be composed of a compositionally same, or compositionally different ILD material than the ILD material that provides the dielectric material pillar 26 and/or the first frontside ILD layer 36. The second frontside ILD layer 48 can be formed be a deposition process including, but not limited to, CVD, PECVD or spin-on coating. A planarization process such as, for example, CMP, can follow the deposition of the ILD material. In the illustrated embodiment, the second frontside ILD layer 48 has a topmost surface that is substantially coplanar with a topmost surface of the hard mask cap 20, a topmost surface of the dielectric material pillar 26, the first frontside ILD layer 36 second dielectric material cap 43.

Although the present application describes and illustrates forming the first type S/D region 34 prior to forming the second type S/D region 46, the processing described above can be reversed to form the second type S/D region 46 prior to forming the first type S/D region 34. In such embodiments, the first dielectric material cap 33 would remain on top of the recessed sacrificial spacer 24 instead of the second dielectric material cap 43 shown in FIG. 13C, for example.

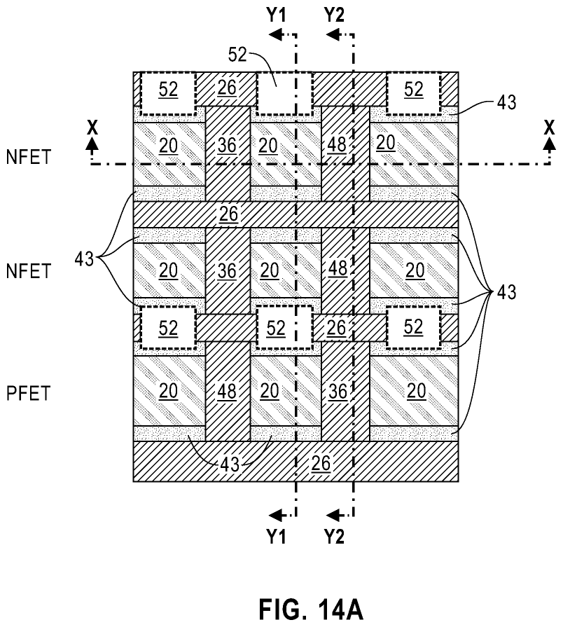

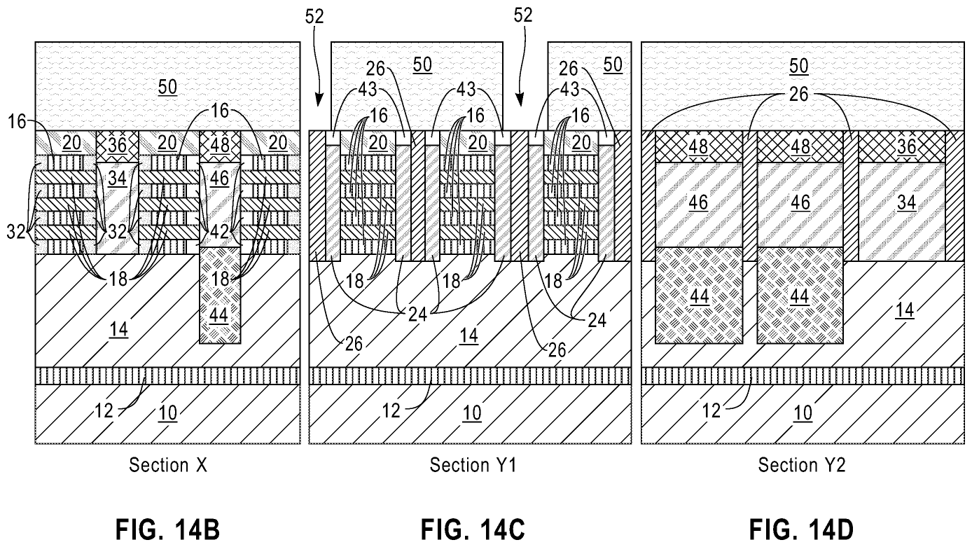

Referring now to FIGS. 14A-14D, there are illustrated the exemplary semiconductor structure shown in FIGS. 13A-13D, respectively, after replacement gate patterning lithography. The replacement gate patterning lithography includes forming patterned OPL 50 have openings 52 formed therein. Openings 52 physically expose the dielectric material pillar 26 and the second dielectric material cap 43 that is located on the sacrificial spacer 24. The patterned OPL layer 50 can be formed as described above for patterned OPL layer 28.

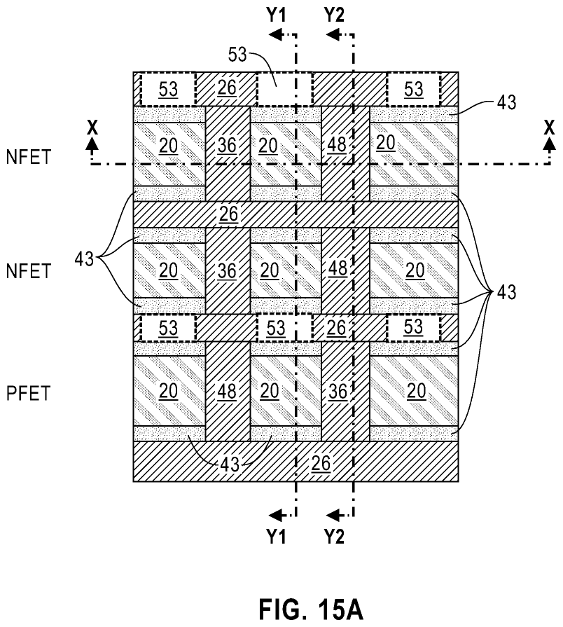

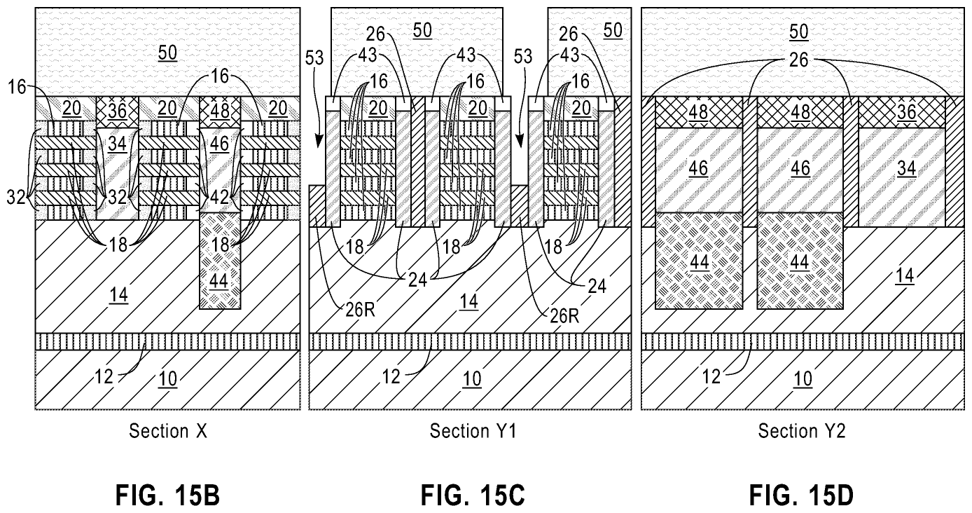

Referring now to FIGS. 15A-15D, there are illustrated the exemplary semiconductor structure shown in FIGS. 14A-14D, respectively, after replacement gate patterning. Replacement gate patterning includes recessing (via an etching process such as, for example, RIE) the dielectric material pillar 26 to provide a recessed dielectric material pillar 26. This recessing extends openings 52 forming gate openings 53 that physically exposed a sidewall of the sacrificial spacers 24.

Referring now to FIGS. 16A-16D, there are illustrated the exemplary semiconductor structure shown in FIGS. 15A-15D, respectively, after removing the sacrificial spacer 24 and the sacrificial semiconductor material nanosheets 16 and forming a gate structure 54. Since the sacrificial spacer 24 and the sacrificial semiconductor material nanosheets 16 are each composed of the third semiconductor material and thus have the same etch rate, the sacrificial spacer 24 and the sacrificial semiconductor material nanosheets 16 are removed simultaneously utilizing an etching process that is selective in removing the third semiconductor material that provides the sacrificial spacer 24 and the sacrificial semiconductor material nanosheets 16. This removal step provides an area in which the gate structure 54 is formed and suspends each of the semiconductor channel material nanosheets 18. This removal step occurs through the gate openings 53. The removal of the sacrificial spacer 24 forms an underhanging region beneath the second dielectric material cap 43 (of first dielectric material cap 33 when the processing of forming the first and second type S/D regions are reversed).

The gate structure 54 is formed in the area previously accompanied by the sacrificial spacer 24 and the sacrificial semiconductor material nanosheets 16, and is formed in the underhanging region that is beneath the second dielectric material cap 43 (or the first dielectric material cap 33 when the processing of forming the first and second type S/D regions are reversed). The gate structure 54 wraps around each of the semiconductor material nanosheets 18 within each nanosheet stack. The gate structure 54 includes a gate dielectric layer and a gate electrode; both the gate dielectric layer and the gate electrode are not separately shown in the drawing, but both are included in the area shown as the gate structure 54. As is known, the gate dielectric layer is formed directly around the suspended portion of each semiconductor channel material nanosheet 18 and the gate electrode is formed on the gate dielectric layer. The gate dielectric layer of the gate structure 54 is composed of a gate dielectric material that has a dielectric constant of greater than 4.0. Illustrative examples of gate dielectric materials that can be used in providing the gate dielectric layer include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode of the gate structure 54 is composed of a gate electrode material. The gate electrode material can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 54 can be formed by deposition of the gate dielectric material and the gate electrode material, followed by a planarization.

In the present application, a gate extension region of the gate structure 54 is formed in the underhanging region that is located beneath the second dielectric material cap 43 (or the first dielectric material cap 33, when the processing of forming the first and second type S/D regions are reversed). In the present application, the dielectric material pillar 26 that is not recessed (hereinafter the non-recessed dielectric material pillar 26 can be referred to a first dielectric material pillar having a first height) provides a cell boundary between the gate structures 54 of two different CMOS cells; i.e., Cell 1 and Cell 2 shown in FIG. 16C. The first dielectric material pillar electrically isolates the gate structures of the two different CMOS cells from one another.

In the present application, the recessed dielectric material pillar 26R (hereinafter the recessed dielectric material pillar 26R can be referred to as a second dielectric material pillar having a second height that is less than the first height). In the region including the second dielectric material pillar, the gate structure 54 within a given CMOS cell (i.e., Cell 2 for example, shown in FIG. 16C) are electrically connected. Within a given CMOS cell, the gate structure 54 is shared between the two complementary NS-FETs.

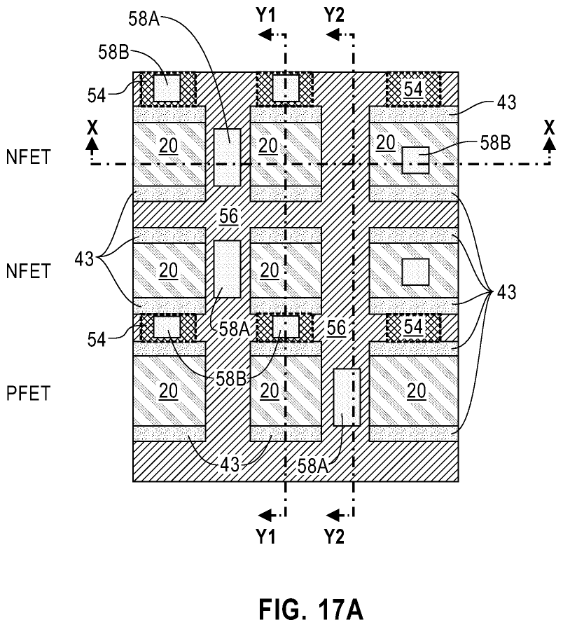

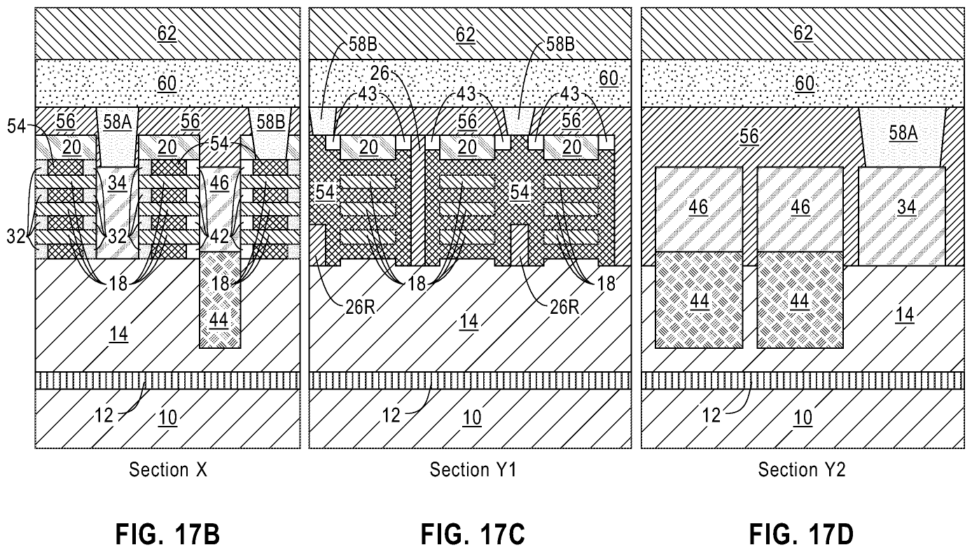

Referring now to FIGS. 17A-17D, there are illustrated the exemplary semiconductor structure shown in FIGS. 16A-16D, respectively, after forming an additional frontside ILD layer to provide a middle-of-the line (MOL) dielectric layer 56, forming frontside contact structures, a frontside BEOL structure 60, and a carrier wafer 62.

The additional frontside ILD layer includes one of the ILD materials mentioned above for the dielectric material pillar 26. The dielectric material that provides the additional frontside ILD layer can be compositionally the same as, or compositionally different from, the dielectric material that provides the first frontside ILD layer 36 and/or the second frontside ILD layer 48. In the present application, the additional frontside ILD layer, the first frontside ILD layer 36 and the second frontside ILD layer 48 collectively provide the MOL dielectric layer 56. The additional frontside ILD layer can be formed utilizing one of the deposition processes mentioned above in forming the first frontside ILD layer 36.

The frontside contact structures are now formed into the MOL dielectric layer 56. The frontside contact structures include at least one frontside source/drain contact structure 58A and at least one frontside gate contact structure 58B. The frontside contact structures are formed utilizing a metallization process. The metallization process includes forming contact openings in the MOL dielectric layer 56 and then filling (including deposition and planarization) those contact openings with at least a contact conductor material. The contact conductor material that can be used for providing the frontside contact structures includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co. Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

In the present application, each frontside source/drain contact structure 58A is formed in contact with the first type S/D region 34, while each frontside gate contact structure 58B contacts a surface of gate electrode of the gate structure 54. Each frontside source/drain contact structure 58A electrically contacts the first type S/D region 34 of one of the nanosheet FETs to the frontside BEOL structure 60. Each frontside gate contact structure 58B electrically contacts the gate electrode of one of the nanosheet FETs to the frontside BEOL structure 60.

Next, frontside BEOL structure 60 is formed on the uppermost surface of the MOL dielectric layer 56. The frontside BEOL structure 60 can include one or more interconnect dielectric material layers (including one of the dielectric materials mentioned above for the first frontside ILD layer 36) that contain frontside metal wires (the metal wires can be composed of any electrically conductive metal or electrically conductive metal alloy) embedded therein. Electrical contact of the frontside BEOL structure 60 to each frontside contact structure is made.

The carrier wafer 62 can include one of the semiconductor materials mentioned above for the first semiconductor layer 10. Carrier wafer 62 is bonded to the frontside BEOL structure 60 after frontside BEOL structure 60 formation. This concludes the frontside processing of the semiconductor device of the present application.

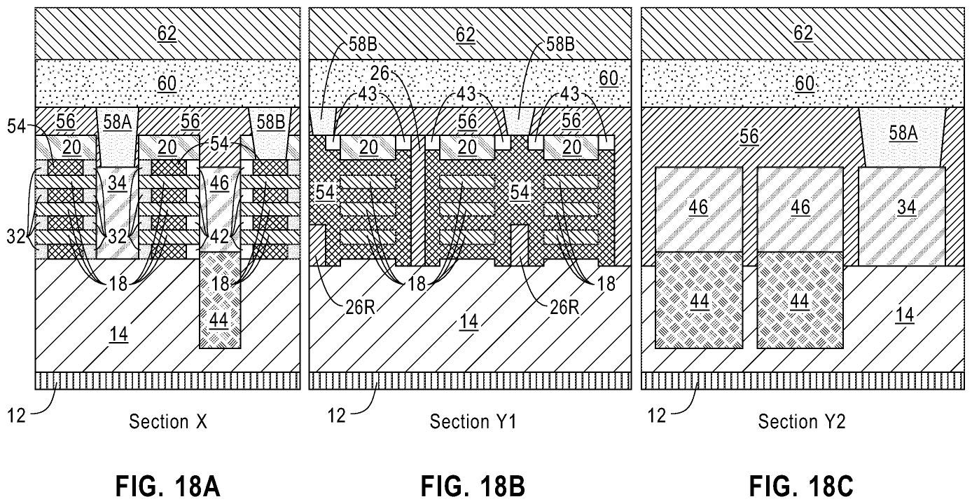

Referring now to FIGS. 18A-18C, there are illustrated the exemplary semiconductor structure shown in FIGS. 17B-17D, respectively, after removing the first semiconductor layer 10 of the substrate. The removal of the first semiconductor layer 10 typically includes flipping the wafer 180° to physically expose a backside of the substate. This flipping step is not shown in the drawings of the present application for clarity. The flipping physically exposes the first semiconductor layer 10 and will allow backside processing of the exemplary structure. Flipping can be performed by hand or by utilizing a mechanical means such as, for example, a robot arm. In the illustrated embodiment, the removal of the physically exposed first semiconductor layer 10 physically exposes the etch stop layer 12. The removal of the first semiconductor layer 10 can be performed utilizing a material removal process that is selective in removing the first semiconductor material that provides the first semiconductor layer 10. The step can be omitted in embodiments in which the substrate does not include first semiconductor layer 10.

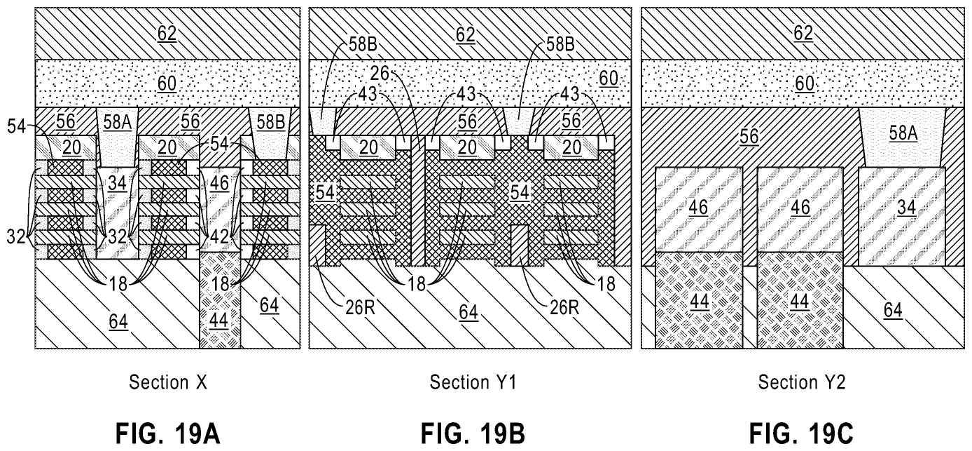

Referring now to FIGS. 19A-19C, there are illustrated the exemplary semiconductor structure shown in FIGS. 18A-18C, respectively, after removing the etch stop layer 12 and the second semiconductor layer 14 of the substrate, and forming a first backside ILD layer 64. The removal of the etch stop layer 12 includes a material removal process that is selective in removing the etch stop layer 12. The removal of the etch stop layer 12 physically exposes the second semiconductor layer 14. The physically exposed second semiconductor layer 14 can be removed utilizing a material removal process that is selective in removing that layer from the structure.

Next, the first backside ILD layer 64 is formed. The first backside ILD layer 64 includes one of the ILD materials mentioned above for the dielectric material pillar 26. The first backside ILD layer 48 can be formed utilizing one of the deposition processes mentioned above in forming the first frontside ILD layer 36. The first backside ILD layer 64 embeds the backside source/drain contact placeholder structure 44.

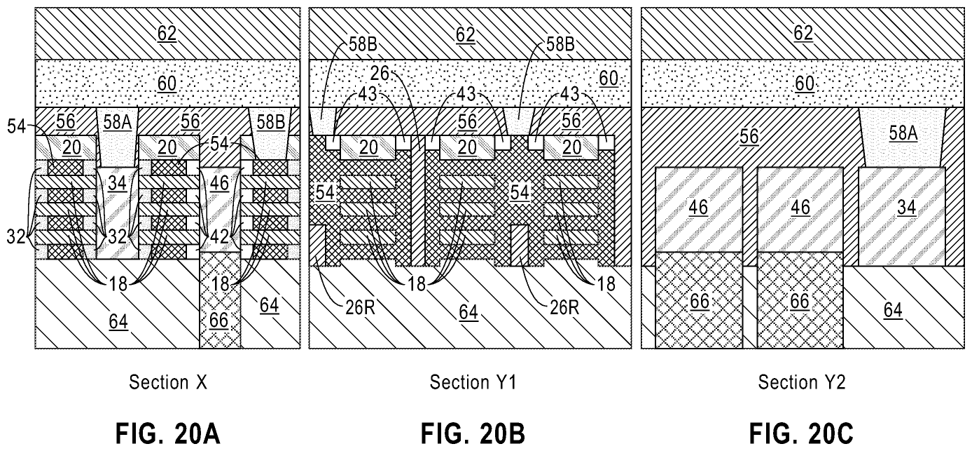

Referring now to FIGS. 20A-20C, there are illustrated the exemplary semiconductor structure shown in FIGS. 19A-19C, respectively, after replacing each backside source/drain contact placeholder structure 44 with a backside source/drain contact structure 66. The replacing of the backside source/drain contact placeholder structures 44 includes a material removal process such as, for example, an etch, that is selective in removing the backside source/drain contact placeholder structure 44. This removal reveals a surface of the second type S/D regions 46. This removal step forms backside source/drain contact openings in the first backside ILD layer 64. The replacing step continues by forming one of the backside source/drain contact structures 66 in each backside source/drain contact opening that is formed in the first backside ILD layer 64. The backside source/drain contact structure 66 is formed in direct physically contact with the physically exposed surface of the second type S/D region 46.

Backside source/drain contact structure 66 includes filling (including deposition and planarization) the backside source/drain contact openings with at least a contact conductor material, as defined above. Notably, the contact conductor material that can be used for providing backside source/drain contact structure 66 includes, for example, a silicide liner, such as Ni, Pt. NiPt, an adhesion metal liner, such as TiN, and conductive metals such as W, Cu, Al, Co, Ru, Mo, Os, Ir, Rh, or an alloy thereof. The backside source/drain contact structure 66 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W. Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. In the present application, the backside source/drain contact structure 66 are self-aligned to the second type S/D regions 46. That is, the sidewalls of the backside source/drain contact structure 66 are vertically aligned with the sidewalls of the second type S/D region 46.

Referring now to FIGS. 21A-21C, there are illustrated the exemplary semiconductor structure shown in FIGS. 20A-20C, respectively, after forming an additional backside ILD layer, forming backside power rail structures, and a backside interconnect structure 70. The additional backside ILD layer includes one of the ILD materials mentioned above for the dielectric material pillar 26. The dielectric material that provides the additional backside ILD layer can be compositionally the same as, or compositionally different from, the dielectric material that provides the first backside ILD layer 64. In the present application, the additional backside ILD layer and the first backside ILD layer 64 collectively provide a backside ILD structure 68. The additional backside ILD layer can be formed utilizing one of the deposition processes mentioned above in forming the first frontside ILD layer 36. In the present application, the additional backside ILD layer will include backside power rail structures. VSS power rails and VDD power rails embedded therein. In the present application, the VDD power rail supplies power, while the VSS power rail is ground.

The VSS power rails (labeled VSS) and the VDD power rails (labeled VDD) are composed of any electrically conductive power rail material including, but not limited to, tungsten (W), cobalt (Co), ruthenium (Ru), aluminum (Al), copper (Cu), platinum (Pt), rhodium (Rh), or palladium (Pd). A diffusion barrier, not shown, can be present on at least the sidewalls of the VSS power rails and the VDD power rails. These power rails are located on the backside of the device and can be formed utilizing a damascene process in which openings are formed in the additionally backside ILD layer and those openings are then filled with at least one of the electrically conductive power rail materials mentioned above. The filling of the openings can include a deposition process such as, for example, CVD, PECVD, ALD, sputtering or plating. A planarization process can follow the deposition process. In other embodiments, a substrative etching process can be used in which the VSS power rails and the VDD power rails are first formed by deposition of a layer of an electrically conductive power rail material, followed by patterning the deposited layer of electrically conductive power rail material into the VSS power rails and VDD power rails. The additional backside ILD layer can then be formed to embed the VSS power rails and the VDD power rails.

The backside interconnect structure 70 is then formed in contact with the additional backside ILD layer that includes the backside power rails, VSS power rails and the VDD power rails. The backside interconnect structure 70. The backside interconnect structure 70 includes ILD layers having backside metal wires (the metal wires can be composed of any electrically conductive metal or electrically conductive metal alloy) embedded therein In the present application, backside interconnect structure 70 is electrically connected to the VSS power rails and the VDD power rails.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first complementary metal oxide semiconductor (CMOS) cell including a first pair of complementary nanosheet field effect transistors comprising a first shared gate structure;
a second CMOS cell including a second pair of complementary nanosheet field effect transistors comprising a second shared gate structure;
a first dielectric material pillar having a first height separating the first shared gate structure of the first CMOS cell from the second shared gate structure of the second CMOS cell;
a second dielectric material pillar having a second height that is less than the first height, wherein the second dielectric material pillar is located between the complementary nanosheet field effect transistors of both the first pair of complementary nanosheet field effect transistors and the second pair of complementary nanosheet field effect transistors;
a hard mask cap located above each of the complementary nanosheet field effect transistors of both the first pair of complementary nanosheet field effect transistors and the second pair of complementary nanosheet field effect transistors, wherein the hard mask cap has outermost edges that are substantially vertically aligned to outermost edges of each semiconductor channel material nanosheet of the complementary nanosheet field effect transistors of the first pair of complementary nanosheet field effect transistors and the second pair of complementary nanosheet field effect transistors in a direction perpendicular to both the first shared gate structure and the second shared gate structure, and the hard mask cap extends horizontally beyond each semiconductor channel material nanosheet of the complementary nanosheet field effect transistors of the first pair of complementary nanosheet field effect transistors and the second pair of complementary nanosheet field effect transistors in a direction parallel to the both the first shared gate structure and the second shared gate structure; and
a dielectric material cap extending outward from each of the outermost edges of the hard mask cap in the direction parallel to the both the first shared gate structure and the second shared gate structure.

2. The semiconductor device of claim 1, wherein the dielectric material cap has a topmost surface that is substantially coplanar with a topmost surface of the hard mask cap and a bottommost surface that is vertically offset, and located above, a bottommost surface of the hard mask cap.

3. The semiconductor device of claim 1, wherein the dielectric material cap has a first sidewall contacting one of the outermost sidewalls of the hard mask cap and a second sidewall contacting a sidewall of the first dielectric material pillar that separates the first CMOS cell from the second CMOS cell.

4. The semiconductor device of claim 1, wherein each of the first shared gate structure, the second shared gate structure, the first dielectric material pillar and the second dielectric material pillar is located directly on a surface of a backside interlayer dielectric (ILD) material of a backside ILD structure.

5. The semiconductor device of claim 1, wherein each complementary nanosheet field effect transistor of the first pair of complementary nanosheet field effect transistors and the second pair of complementary nanosheet field effect transistors has a first type source/drain (S/D) region and a second type S/D region.

6. The semiconductor device of claim 5, further comprising first inner spacers located adjacent to the first type S/D region, and second inner spacers located adjacent to the second type S/D region, wherein the first inner spacers are composed of a first spacer dielectric material having a first dielectric constant and the second inner spacers are composed of a second spacer dielectric material having a second dielectric constant which differs from the first dielectric constant.

7. The semiconductor device of claim 6, wherein the second dielectric constant is less than the first dielectric constant.

8. The semiconductor device of claim 7, wherein the first type S/D region is a drain region, and the second type S/D region is a source region.

9. The semiconductor device of claim 7, wherein the dielectric material cap is composed of the second spacer dielectric material.

10. The semiconductor device of claim 7, wherein the dielectric material cap is composed of the first spacer dielectric material.

11. The semiconductor device of claim 5, further comprising a frontside back-end-on-the-line (BEOL) structure electrically connected to the first type S/D region by a frontside source/drain contact structure.

12. The semiconductor device of claim 11, further comprising a frontside gate contact structure electrically connecting each of the first shared gate structure and the second shared gate structure to the frontside BEOL structure.

13. The semiconductor device of claim 12, wherein the frontside gate contact structure is located above the second dielectric material pillar and is in contact with at least a portion of the topmost surface of the dielectric material cap.

14. The semiconductor device of claim 13, further comprising a carrier wafer located on the frontside BEOL structure.

15. The semiconductor device of claim 5, further comprising a VSS power rail electrically connected to the second type S/D region by a backside frontside source/drain contact structure.

16. The semiconductor device of claim 15, further comprising a backside interconnect structure located on a surface of the backside VSS power rail.

17. The semiconductor device of claim 16, further comprising a backside VDD power rail spaced apart from the backside VSS power rail and located on the backside interconnect structure.

18. The semiconductor device of claim 5, wherein in the direction parallel to the both the first shared gate structure and the second shared gate structure an outermost edge of each of the first inner spacers are substantially vertically aligned to one of the outermost edges of the hard mask cap and an outermost edge of each of the second inner spacers are substantially vertically aligned to another of the outermost edges of the hard mask cap.

19. The semiconductor device of claim 1, wherein the first dielectric material pillar has a topmost surface that is substantially coplanar with a topmost surface of the dielectric material cap and a topmost surface of the hard mask cap.

20. The semiconductor device of claim 19, wherein the first dielectric material pillar and the second dielectric material pillar are each composed of a same interlayer dielectric material.
